(19) United States
(12) Patent Application Publication
(10) Pub. No.: US 2025/0224618 A1
(43) Pub. Date: Jul. 10, 2025

(54) DISPLAY DEVICE, AND HEAD MOUNT DISPLAY DEVICE INCLUDING THE SAME

(71) Applicant: Samsung Display Co., LTD., Yongin-si (KR)

(72) Inventors: Sang Yong NO, Yongin-si (KR); Gi Chang LEE, Yongin-si (KR)

(21) Appl. No.: 18/919,193

(22) Filed: Oct. 17, 2024

(30) Foreign Application Priority Data
Jan. 5, 2024 (KR) 10-2024-0002153

(51) Int. Cl. G02B 27/01; G09G 3/00

(52) U.S. Cl. CPC G02B 27/0176; G02B 27/0172; G09G 3/002; G02B 2207/101

(57) ABSTRACT

A head mounted display device includes a display device. A display device includes: a first single crystal semiconductor substrate on which first transistors are located; a second single crystal semiconductor substrate on the first single crystal semiconductor substrate, the second single crystal semiconductor substrate having a display area; a plurality of sub-pixels including light emitting elements at the display area of the second single crystal semiconductor substrate, a plurality of first through holes having first conductive vias electrically connected to a plurality of data lines connected to the plurality of sub-pixels, and a plurality of second through holes having second conductive vias electrically connected to a gate driver electrically connected to the sub-pixels; and a heat dissipating member around the first single crystal semiconductor substrate below the second single crystal semiconductor substrate and overlapping each of the plurality of first through holes and the second through holes.

### CROSS-REFERENCE TO RELATED APPLICATION

The present application claims priority to, and the benefit of, Korean Patent Application No. 10-2024-0002153, filed on Jan. 5, 2024, in the Korean Intellectual Property Office, the entire disclosure of which is incorporated by reference herein.

### BACKGROUND

### 1. Field

The present disclosure relates to a display device and a head mounted display device including the same.

### 2. Description of the Related Art

A head mounted display (HMD) device is an image display device that is worn on a user's head in the form of glasses or a helmet and forms a focus at a distance close to user's eyes in front of the user's eyes. The head mounted display device may implement virtual reality (VR) or augmented reality (AR).

The head mounted display device magnifies and displays an image displayed by a small display device using a plurality of lenses. Therefore, a display device applied to the head mounted display device needs to provide a high-resolution image, for example, an image having a resolution of 3,000 pixels per inch (PPI) or more. To this end, an organic light emitting diode on silicon (OLEDoS), which is a small organic light emitting display device having a high resolution, has been used as the display device applied to the head mounted display device. The OLEDOS is a device that displays an image by disposing organic light emitting diodes (OLEDs) on a semiconductor wafer substrate on which complementary metal oxide semiconductors (CMOSs) are disposed.

### Summary

Aspects and features of embodiments of the present disclosure provide a micro-display device including a plurality of different single crystal semiconductor substrates, and a head mounted display device including the same.

Aspects and features of embodiments of the present disclosure also provide a display device capable of reducing or minimizing an arrangement area of through holes connecting two different semiconductor substrates to each other and effectively dissipating heat generated at a connection portion between the two different semiconductor substrates, and a head mounted display device including the same.

However, aspects and features of embodiments of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a display device including: a first single crystal semiconductor substrate on which a plurality of first transistors are located; a second single crystal semiconductor substrate on the first single crystal semiconductor substrate, the second single crystal semiconductor substrate having a display area; a plurality of sub-pixels including light emitting elements at the display area of the second single crystal semiconductor substrate, a plurality of first through holes having first conductive vias electrically connected to a plurality of data lines connected to the plurality of sub-pixels, and a plurality of second through holes having second conductive vias electrically connected to a gate driver electrically connected to the sub-pixels; and a heat dissipating member around the first single crystal semiconductor substrate below the second single crystal semiconductor substrate and overlapping each of the plurality of first through holes and the second through holes, wherein the heat dissipation member includes a first heat dissipation layer in contact with each of a lower surface and side surfaces of the first single crystal semiconductor substrate and a first heat dissipation substrate on a lower surface of the first heat dissipation layer, and wherein an area of the first single crystal semiconductor substrate in a plan view is smaller than an area of the second single crystal semiconductor substrate in a plan view.

In one or more embodiments, the first heat dissipation layer covers the lower surface and the side surfaces of the first single crystal semiconductor substrate and overlaps a portion of a lower surface of the second single crystal semiconductor substrate that does not overlap the first single crystal semiconductor substrate, and wherein the heat dissipation member further includes a second heat dissipation substrate overlapping a portion of the second single crystal semiconductor substrate where the first single crystal semiconductor substrate is not located.

In one or more embodiments, the first heat dissipation layer overlaps the display area in a thickness direction of the display device.

In one or more embodiments, the display device further includes a circuit board on the second single crystal semiconductor substrate and overlapping the plurality of first through holes, wherein the heat dissipation member further includes a third heat dissipation layer on the circuit board and a third heat dissipation substrate on the third heat dissipation layer.

In one or more embodiments, the third heat dissipation layer is on a portion of the second single crystal semiconductor substrate where the first through holes are located, and wherein the third heat dissipation substrate does not overlap the second single crystal semiconductor substrate.

In one or more embodiments, the second single crystal semiconductor substrate further includes a plurality of third through holes overlapping pads, and wherein the plurality of first through holes overlap the circuit board in a thickness direction of the display device.

In one or more embodiments, outer side surfaces of each of the first heat dissipation layer, the first heat dissipation substrate, and the second heat dissipation substrate are parallel to side surfaces of the second single crystal semiconductor substrate.

In one or more embodiments, outer side surfaces of each of the first heat dissipation layer, the first heat dissipation substrate, and the second heat dissipation substrate protrude outward more than side surfaces of the second single crystal semiconductor substrate.

In one or more embodiments, the heat dissipation member further includes a heat blocking layer between the first single crystal semiconductor substrate and the second single crystal semiconductor substrate, wherein the heat blocking layer includes a plurality of through holes in which connection lines penetrating through the heat blocking layer and electrically connected respectively to the first conductive vias and the second conductive vias are located.

In one or more embodiments, the first heat dissipation layer overlaps the first single crystal semiconductor substrate, and wherein at least a portion of the second single crystal semiconductor substrate does not overlap the first heat dissipation layer.

In one or more embodiments, the first heat dissipation layer covers the lower surface and the side surfaces of the first single crystal semiconductor substrate, and wherein the heat dissipation member further includes a second heat dissipation layer overlapping a portion of a lower surface of the second single crystal semiconductor substrate that does not overlap the first single crystal semiconductor substrate, and a second heat dissipation substrate on a lower surface of the second heat dissipation layer.

In one or more embodiments, the display device further includes a circuit board on the second single crystal semiconductor substrate and overlapping the plurality of first through holes, wherein the heat dissipation member further includes a third heat dissipation layer on the circuit board and a third heat dissipation substrate on the third heat dissipation layer.

In one or more embodiments, a number of the first through holes is the same as a number of pixel columns of the sub-pixels arranged in the display area.

In one or more embodiments, the data lines extend in a first direction on the second single crystal semiconductor substrate, and are electrically connected to at least some of the first transistors, wherein the display device further includes a plurality of scan lines extending in a second direction crossing the first direction on the second single crystal semiconductor substrate and electrically connected to the gate driver, and wherein the number of the first through holes is the same as a number of data lines.

In one or more embodiments, a width of the first single crystal semiconductor substrate measured in one direction is greater than a width of the display area measured in the one direction.

In one or more embodiments, a head mounted display device includes: a frame; a plurality of display devices in the frame; and lenses on the plurality of display devices, respectively, wherein the display device includes: a first single crystal semiconductor substrate on which a plurality of first transistors are located; a second single crystal semiconductor substrate disposed on the first single crystal semiconductor substrate, the second single crystal semiconductor substrate having a display area; a plurality of sub-pixels including light emitting elements at the display area of the second single crystal semiconductor substrate; a plurality of first through holes having first conductive vias electrically connected to a plurality of data lines connected to the plurality of sub-pixels are disposed, and a plurality of second through holes having second conductive vias electrically connected to a gate driver electrically connected to the sub-pixels; and a heat dissipating member around the first single crystal semiconductor substrate below the second single crystal semiconductor substrate and overlapping each of the plurality of first through holes and the second through holes, the heat dissipation member including a first heat dissipation layer in contact with each of a lower surface and side surfaces of the first single crystal semiconductor substrate and a first heat dissipation substrate disposed on a lower surface of the first heat dissipation layer, and an area of the first single crystal semiconductor substrate in a plan view is smaller than an area of the second single crystal semiconductor substrate in a plan view.

In one or more embodiments, the first heat dissipation layer covers the lower surface and the side surfaces of the first single crystal semiconductor substrate and overlaps a portion of a lower surface of the second single crystal semiconductor substrate that does not overlap the first single crystal semiconductor substrate, and wherein the heat dissipation member further includes a second heat dissipation substrate overlapping a portion of the second single crystal semiconductor substrate where the first single crystal semiconductor substrate is not located.

In one or more embodiments, the heat dissipation member further includes a heat blocking layer between the first single crystal semiconductor substrate and the second single crystal semiconductor substrate, wherein the heat blocking layer includes a plurality of through holes in which connection lines penetrating through the heat blocking layer and electrically connected respectively to the first conductive vias and the second conductive vias are located.

In one or more embodiments, the first heat dissipation layer overlaps the first single crystal semiconductor substrate, and wherein at least a portion of the second single crystal semiconductor substrate does not overlap the first heat dissipation layer.

In one or more embodiments, the first heat dissipation layer covers the lower surface and the side surfaces of the first single crystal semiconductor substrate, and wherein the heat dissipation member further includes a second heat dissipation layer overlapping a portion of a lower surface of the second single crystal semiconductor substrate that does not overlap the first single crystal semiconductor substrate, and a second heat dissipation substrate disposed on a lower surface of the second heat dissipation layer.

The display device according to one or more embodiments may include two different single crystal semiconductor substrates, and in a manufacturing process of a single crystal semiconductor substrate disposed below, a large number of driving units may be manufactured per unit wafer substrate, such that a manufacturing yield of the driving unit may be improved.

In addition, in the display device according to one or more embodiments, circuit units may be disposed separately on the two different single crystal semiconductor substrates, and the number of through holes connecting the circuit units disposed separately on the two different single crystal semiconductor substrates to each other may be minimized. The display devices may alleviate a high degree of integration on a single crystal semiconductor substrate having a small area. Furthermore, the display device may effectively manage heat generation by further including heat dissipation members dissipating heat generated from portions disposed in the through holes.

However, aspects according to the embodiments of the present disclosure are not limited to the above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view of a display device according to one or more embodiments;

FIG. 2 is a plan view illustrating an example of a driving unit illustrated in FIG. 1;

FIG. 3 is a plan view illustrating an example of a display unit illustrated in FIG. 1;

FIG. 4 is a plan view illustrating an arrangement of a plurality of lines disposed in the display unit of FIG. 3;

FIG. 5 is a block diagram illustrating the display device according to one or more embodiments;

FIG. 6 is an equivalent circuit diagram of one sub-pixel according to one or more embodiments;

FIG. 7 is a schematic view illustrating a rear surface of the display device according to one or more embodiments;

FIG. 8 is a schematic cross-sectional view of the display device according to one or more embodiments;

FIG. 9 is a schematic cross-sectional view of the driving unit according to one or more embodiments;

FIG. 10 is a plan view illustrating first electrodes and emission areas of a plurality of sub-pixels and a pixel defining film that are disposed in a display area of the display unit according to one or more embodiments;

FIG. 11 is a plan view illustrating first electrodes and emission areas of a plurality of sub-pixels and a pixel defining film that are disposed in a display area of a display unit according to one or more embodiments;

FIGS. 12 and 13 are cross-sectional views illustrating the display area and a portion of a non-display area of the display unit according to one or more embodiments;

FIG. 14 is a schematic cross-sectional view of a display device according to one or more embodiments;

FIGS. 15 to 18 are schematic cross-sectional views of display devices according to still another embodiment;

FIG. 19 is a perspective view illustrating a head mounted display device according to one or more embodiments;

FIG. 20 is an exploded perspective view illustrating an example of the head mounted display device of FIG. 19; and

FIG. 21 is a perspective view illustrating a head mounted display device according to one or more embodiments.

### DETAILED DESCRIPTION

Aspects and features of embodiments of the present disclosure and methods of accomplishing the same may be understood more readily by reference to the detailed description of embodiments and the accompanying drawings. The described embodiments are provided as examples so that the present disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, and/or portion. Thus, a first element, component, region, layer or section described below could be termed a second element, component, region, layer or section, without departing from the spirit and/or scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the spirit or scope of the present disclosure. In addition, in one or more embodiments, the block, unit and/or module may be physically combined into more complex blocks, units, and/or modules without departing from the spirit or scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present disclosure, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

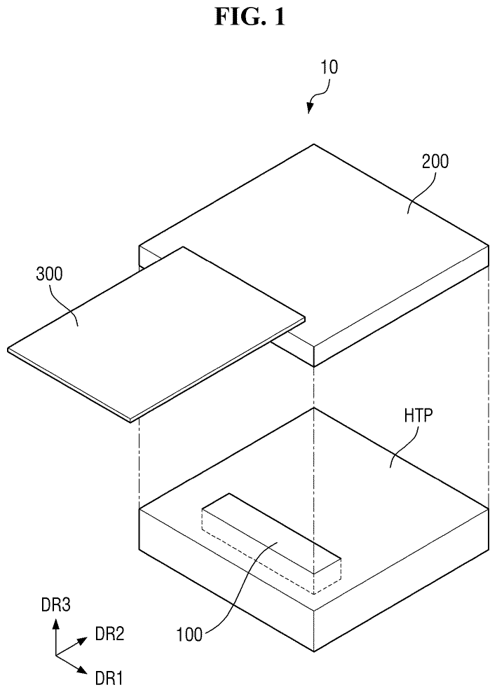

FIG. 1 is an exploded perspective view of a display device according to one or more embodiments.

Referring to FIG. 1, a display device 10 according to one or more embodiments is a device that displays a moving image and/or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 may be applied as a display unit of televisions, laptop computers, monitors, billboards, and/or the Internet of Things (IOTs). Alternatively, the display device 10 may be applied to smart watches, watch phones, and/or head mounted display (HMD) devices for realizing virtual reality and augmented reality.

The display device 10 according to one or more embodiments may include a driving unit 100, a display unit 200, and a circuit board 300. The display device 10 may include a heat dissipation member HTP disposed around the driving unit 100.

The driving unit 100 may have a shape similar to a quadrangular shape in a plan view. For example, the driving unit 100 may have a shape similar to a rectangular shape, in a plan view, having on side in a first direction DR1 and the other side in a second direction DR2 crossing the first direction DR1. In the driving unit 100, one side in the first direction DR1 and the other side in the second direction DR2 may have different lengths. In the driving unit 100, a corner where one side in the first direction DR1 and the other side in the second direction DR2 meet may be rounded with a suitable curvature (e.g., a predetermined curvature) or right-angled. A shape of the driving unit 100 in a plan view is not limited to the quadrangular shape, and may be a shape similar to other polygonal shapes, a circular shape, and/or an elliptical shape.

The display unit 200 may be disposed on the driving unit 100. In the display device 10, the driving unit 100 and the display unit 200 may be bonded to each other. The display unit 200 may have a shape similar to a square shape unlike the driving unit 100. For example, the display unit 200 may have a shape similar to a square shape in a plan view in which one side in the first direction DR1 and the other side in the second direction DR2 crossing the first direction DR1 have the same length. A shape of the display unit 200 in a plan view is not limited to the square shape, and may be a shape similar to other polygonal shapes, a circular shape, or an elliptical shape. A shape of the display device 10 in a plan view may follow the shape of the display unit 200 in a plan view, but is not limited thereto.

According to one or more embodiments, in the display device 10, an area of the display unit 200 in a plan view may be greater than an area of the driving unit 100 in a plan view. The display device 10 may include the driving unit 100 and the display unit 200 that include different substrates, and the driving unit 100 and the display unit 200 may have different areas. Elements formed in the driving unit 100 and elements formed in the display unit 200 may be different from each other, and these elements may be individually formed on different substrates, respectively. The display device 10 may be manufactured by forming a plurality of elements of which sizes, line widths, manufacturing processes, and the like, are different from each other on different substrates and then bonding the plurality of elements to each other, and the performance, a manufacturing yield, and/or the like, of a product may be improved.

The circuit board 300 may be electrically connected to a plurality of pads of a pad area of the display unit 200 using a conductive adhesive member such as an anisotropic conductive film. The circuit board 300 may be a flexible printed circuit board (FPCB) or a flexible film having a flexible material. It has been illustrated in FIG. 1 that the circuit board 300 is unbent, but the circuit board 300 may be bent. In this case, one end of the circuit board 300 may be disposed on a lower surface of the driving unit 100. The other end of the circuit board 300 may be connected to the plurality of pads of the pad area of the display unit 200 using the conductive adhesive member. In another embodiment, the circuit board 300 may be attached to a lower surface of the driving unit 100.

The heat dissipation member HTM may be around (e.g., may surround) the driving unit 100 and may be disposed on a lower surface of the display unit 200. The heat dissipation member HTM may effectively dissipate heat generated from the driving unit 100 and the display unit 200. The heat dissipation member HTM may include a layer made of graphite and/or a metal such as silver (Ag), copper (Cu), and/or aluminum (Al) having high thermal conductivity. The heat dissipation member HTM will be described in more detail below.

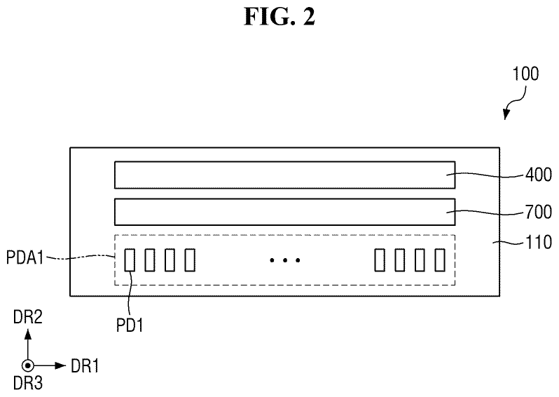

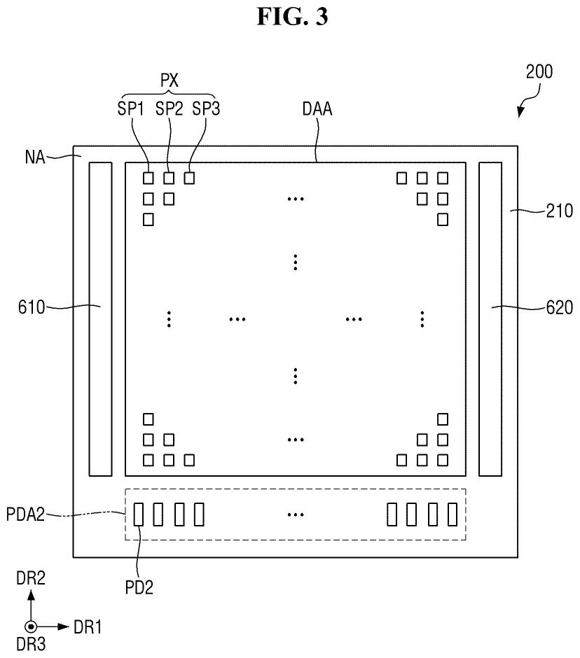

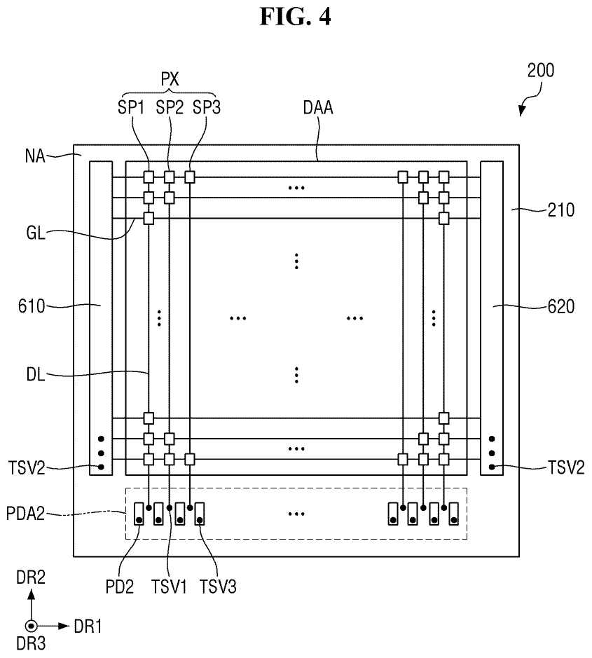

FIG. 2 is a plan view illustrating an example of a driving unit illustrated in FIG. 1. FIG. 3 is a plan view illustrating an example of a display unit illustrated in FIG. 1. FIG. 4 is a plan view illustrating an arrangement of a plurality of lines disposed in the display unit of FIG. 3.

Referring to FIGS. 2-4, the driving unit 100 of the display device 10 may include driving circuit elements of the display device 10. The driving unit 100 may include a first single crystal semiconductor substrate 110, and a driving circuit unit 400 and a data driver 700 that are formed on the first single crystal semiconductor substrate 110.

The first single crystal semiconductor substrate 110 may be a silicon substrate, a germanium substrate, and/or a silicon-germanium substrate. A plurality of first transistors may be formed on the first single crystal semiconductor substrate 110. The plurality of first transistors may be electrically connected to each other to form the driving circuit unit 400 and the data driver 700. The first transistors may be formed through a semiconductor process. For example, the plurality of first transistors may be formed as complementary metal oxide semiconductor (CMOS) transistors.

It has been illustrated in FIG. 2 that the driving circuit unit 400 is disposed on an upper side of the driving unit 100 and the data driver 700 and a first pad area PDA1 are disposed on a lower side of the driving unit 100. However, the present disclosure is not limited thereto. Positions of the driving circuit unit 400 and the data driver 700 in the driving unit 100 may be variously changed depending on a design structure of a plurality of circuit elements formed on the first single crystal semiconductor substrate 110.

The first pad area PDA1 may include a plurality of first pads PD1 disposed along the first direction DR1. The plurality of first pads PD1 may be electrically connected to a plurality of second pads PD2 of the display unit 200, and may be electrically connected to the circuit board 300 through the plurality of second pads PD2. The first pad PD1 may transfer electrical signals applied from the circuit board 300 to the driving circuit unit 400, gate drivers 610 and 620, and the data driver 700.

The display unit 200 may include a second single crystal semiconductor substrate 210, and a plurality of pixels PX and the gate drivers 610 and 620 that are formed on the second single crystal semiconductor substrate 210. The display unit 200 may include a display area DAA where the plurality of pixels PX are disposed and a non-display area NA disposed around the display area DAA. The gate drivers 610 and 620 and a second pad area PDA2 may be disposed in the non-display area NA.

The second single crystal semiconductor substrate 210 may be a silicon substrate, a germanium substrate, and/or a silicon-germanium substrate. A plurality of second transistors may be formed on the second single crystal semiconductor substrate 210. The plurality of second transistors may be electrically connected to each other to form gate drivers 610 and 620 and a pixel circuit unit for emitting light from the plurality of pixels PX. The second transistors may be formed through a semiconductor process. For example, the plurality of second transistors may be formed as CMOS transistors.

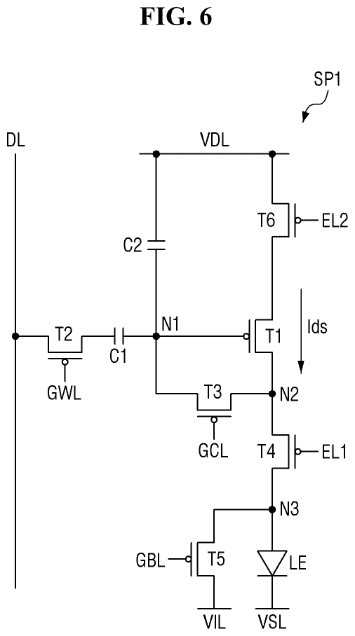

The plurality of pixels PX including light emitting elements may be disposed in the display area DAA. Each of the plurality of pixels PX may include three sub-pixels such as a first sub-pixel SP1, a second sub-pixel SP2, and a third sub-pixel SP3. The three sub-pixels SP1, SP2, and SP3 may constitute one pixel PX to display colors. However, the present disclosure is not limited thereto, and one pixel PX may include three or more sub-pixels. A plurality of sub-pixels SP may be arranged in a matrix form along the first direction DR1 and the second direction DR2. For example, the plurality of sub-pixels SP may be arranged along rows and columns of a matrix along the first direction DR1 and the second direction DR2. Each of the plurality of sub-pixels SP1, SP2, and SP3 may be electrically connected to a pixel circuit (e.g., a pixel circuit in FIG. 6) including the plurality of second transistors formed on the second single crystal semiconductor substrate 210. Each of the sub-pixels SP1, SP2, and SP3 may include light emitting elements, and the light emitting elements may emit light according to electrical signals applied from pixel circuits disposed in the display area DAA.

Some of the sub-pixels SP1, SP2, and SP3 disposed in the display area DAA of the display unit 200 may overlap the driving unit 100 in a thickness direction (e.g., the third direction DR3), and the others of the sub-pixels SP1, SP2, and SP3 may not overlap the driving unit 100. The driving unit 100 may have a smaller area than the display unit 200, and may be disposed adjacent to one side of the display unit 200. Accordingly, only some of the plurality of sub-pixels SP1, SP2, and SP3 may overlap the driving unit 100 in the thickness direction (e.g., the third direction DR3).

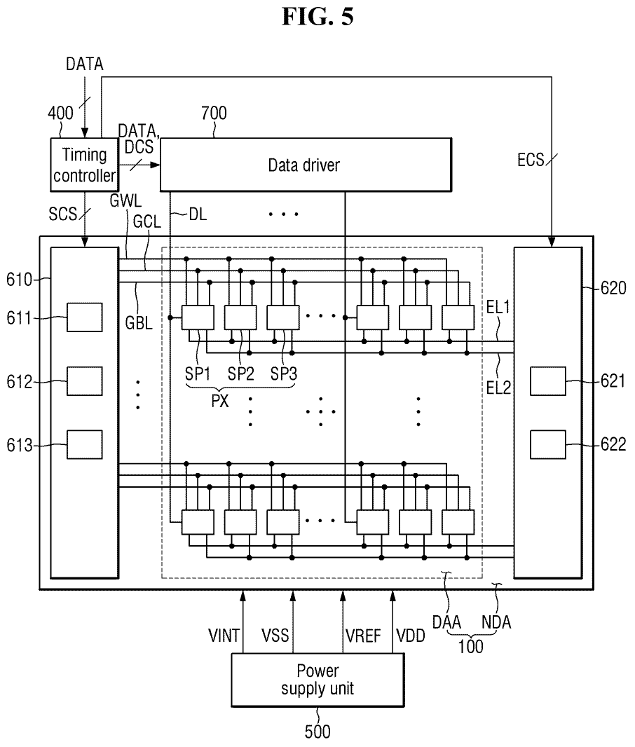

In the display area DAA, a plurality of scan lines GL extending in the first direction DR1 and arranged along the second direction DR2 and a plurality of data lines DL extending in the second direction DR2 and arranged along the first direction DR1 may be disposed. The plurality of scan lines GL may include different types of scan lines such as first to third scan lines GWL, GCL, and GBL (see FIG. 5) and emission control lines EL1 and EL2 (see FIG. 5). The plurality of scan lines GL and data lines DL may be connected to each of the plurality of sub-pixels SP1, SP2, and SP3 of the display area DAA. The plurality of scan lines GL may be electrically connected to the gate drivers 610 and 620 of the display unit 200, and the plurality of data lines DL may be electrically connected to the data driver 700 of the driving unit 100. The data lines DL may be electrically connected to the data driver 700 of the driving unit 100 through first through holes TSV1.

Each of the plurality of sub-pixels SP1, SP2, and SP3 may be electrically connected to the scan line GL and the data line DL. Each of the plurality of sub-pixels SP1, SP2, and SP3 may receive a data voltage of the data line DL according to a scan signal of the scan line GL, and allow the light emitting element to emit light according to the data voltage.

The non-display area NA may be disposed to be around (e.g., to surround) the display area DAA. The non-display area NA may be an area where the pixels PX are not disposed, and accordingly, light is not emitted. The gate drivers 610 and 620, the second pad area PDA2, and a plurality of through holes TSV1, TSV2, and TSV3 may be disposed in the non-display area NA.

The gate drivers 610 and 620 may include a scan driver 610 and an emission driver 620. The scan driver 610 may include a plurality of scan transistors formed on the second single crystal semiconductor substrate 210, and the emission driver 620 may include a plurality of light emitting transistors formed on the second single crystal semiconductor substrate 210. The plurality of scan transistors and the plurality of light emitting transistors may be formed through a semiconductor process. For example, the plurality of scan transistors and the plurality of light emitting transistors may be formed as CMOS transistors.

The scan driver 610 may be disposed on the left side of the display area DAA, which is one side of the display area DAA in the first direction DR1, and the emission driver 620 may be disposed on the right side of the display area DAA, which is the other side of the display area DAA in the first direction DR1. The plurality of scan lines GL may each be electrically connected to one of the scan driver 610 and the emission driver 620. As an example, the first to third scan lines GWL, GCL, and GBL (e.g., see FIG. 5) of the scan lines GL may be connected to the scan driver 610, and the emission control lines EL1 and EL2 (e.g., see FIG. 5) may be connected to the emission driver 620.

The second pad area PDA2 may be disposed on the lower side of the display area DAA, which is one side of the display area DAA in the second direction DR2. The plurality of second pads PD2 arranged along the first direction DR1 may be disposed in the second pad area PDA2. The plurality of second pads PD2 may be electrically connected to the plurality of first pads PD1 of the driving unit 100, and the circuit board 300 may be attached onto the plurality of second pads PD2. The second pads PD2 are electrically connected to the circuit board 300, and may transmit electrical signals applied from the circuit board 300 to the driving unit 100.

The display device 10 may include the plurality of through holes TSV1, TSV2, and TSV3 forming paths through which the elements disposed in the driving unit 100 and the display unit 200 are electrically connected to each other. The plurality of through holes TSV1, TSV2, and TSV3 may be formed to penetrate through the second single crystal semiconductor substrate 210 of the display unit 200. The driving circuit unit 400 and the data driver 700 disposed in the driving unit 100 may be electrically connected to the display unit 200 and the circuit board 300 through connection lines disposed in the through holes TSV1, TSV2, and TSV3.

The plurality of through holes TSV1, TSV2, and TSV3 may include a plurality of first through holes TSV1, second through holes TSV2, and third through holes TSV3 disposed in the non-display area NA.

The first through holes TSV1 may be disposed on one side of the display area DAA in the non-display area NA. For example, the first through holes TSV1 may be disposed on the lower side of the display area DAA. In one or more embodiments, the first through holes TSV1 may be disposed in the second pad area PDA2, and may be disposed so as not to overlap the second pads PD2. The first through holes TSV1 may be disposed to correspond to the plurality of data lines DL disposed in the display area DAA, respectively. The number of first through holes TSV1 may be the same as the number of data lines DL and the number of pixel columns of the plurality of sub-pixels SP1, SP2, and SP3 disposed in the display area DAA. Each of the plurality of data lines DL may correspond to the first through hole TSV1, and may be electrically connected to a connection line disposed in the first through hole TSV1. Each of the sub-pixels SP1, SP2, and SP3 may receive a data signal applied from the data line DL connected to the driving unit 100 through the first through hole TSV1.

The second through holes TSV2 may be disposed in the gate drivers 610 and 620 in the non-display area NA. Some of the plurality of second through holes TSV2 may be disposed to overlap the scan driver 610, and the others of the plurality of second through holes TSV2 may be disposed to overlap the emission driver 620. Connection lines connecting the gate drivers 610 and 620 and the driving unit 100 to each other may be disposed in the second through holes TSV2, and signals for driving the gate drivers 610 and 620 may be applied from the driving unit 100 to the second through holes TSV2. For example, the gate drivers 610 and 620 may be connected to connection lines connected to the driving circuit unit 400 of the driving unit 100 through the second through holes TSV2, and may receive timing signals applied to the gate drivers 610 and 620.

The third through holes TSV3 may be disposed to overlap the second pads PD2, respectively, in the non-display area NA. The third through holes TSV3 may be disposed to correspond to the second pad PD2, respectively, and the number of third through holes TSV3 may be the same as the number of second pads PD2. The second pads PD2 may be electrically connected to the first pads PD1 of the driving unit 100 through connection lines disposed in the third through holes TSV3.

FIG. 5 is a block diagram illustrating the display device according to one or more embodiments.

Referring to FIG. 5, the driving circuit unit 400 may include a timing controller. In addition, the driving circuit unit 400 may further include various circuits involved in driving the display device 10, such as a gamma circuit and a logic circuit. The driving circuit unit 400 may include driving circuit transistors formed on the first single crystal semiconductor substrate 110.

The driving circuit unit 400 may receive digital video data and timing signals from the outside. The timing controller may generate a scan timing control signal SCS, an emission timing control signal ECS, and a data timing control signal DCS for controlling the display unit 200 according to the timing signals. The timing controller may output the scan timing control signal SCS to the scan driver 610 of the gate drivers 610 and 620 and output the emission timing control signal ECS to the emission driver 620 of the gate drivers 610 and 620. The timing controller may output the digital video data DATA and the data timing control signal DCS to the data driver 700.

A power supply unit may generate a plurality of panel driving voltages according to an external source voltage. For example, the power supply unit may generate a first driving voltage VSS, a second driving voltage VDD, a reference voltage VREF, and an initialization voltage VINT and supply the first driving voltage VSS, the second driving voltage VDD, the reference voltage VREF, and the initialization voltage VINT to the plurality of pixels PX.

The scan timing control signal SCS, the emission timing control signal ECS, the digital video data DATA, and the data timing control signal DCS of the driving circuit unit 400 may be supplied to the plurality of pixels PX. The first driving voltage VSS, the second driving voltage VDD, the reference voltage VREF, and the initialization voltage VINT of the power supply unit may also be supplied to the plurality of pixels PX.

The gate drivers 610 and 620 may include the scan driver 610 and the emission driver 620. The scan driver 610 may include a plurality of scan transistors formed on the second single crystal semiconductor substrate 210, and the emission driver 620 may include a plurality of light emitting transistors formed on the second single crystal semiconductor substrate 210. The plurality of scan transistors and the plurality of light emitting transistors may be formed through a semiconductor process. For example, the plurality of scan transistors and the plurality of light emitting transistors may be formed as CMOS transistors.

The scan driver 610 may include a first scan signal output unit 611, a second scan signal output unit 612, and a third scan signal output unit 613. Each of the first scan signal output unit 611, the second scan signal output unit 612, and the third scan signal output unit 613 may receive the scan timing control signal SCS from the driving circuit unit 400. The first scan signal output unit 611 may generate write scan signals according to the scan timing control signal SCS of the driving circuit unit 400 and sequentially output the write scan signals to first scan lines GWL. The second scan signal output unit 612 may generate control scan signals according to the scan timing control signal SCS and sequentially output the control scan signals to second scan lines GCL. The third scan signal output unit 613 may generate bias scan signals according to the scan timing control signal SCS and sequentially output the bias scan signals to third scan lines GBL.

The emission driver 620 may include a first emission signal output unit 621 and a second emission signal output unit 622. Each of the first emission signal output unit 621 and the second emission signal output unit 622 may receive the emission timing control signal ECS from the driving circuit unit 400. The emission driver 620 may generate emission control signals according to the emission timing control signal ECS and sequentially output the emission control signals to first and second emission control lines EL1 and EL2.

The data driver 700 may receive the digital video data DATA and the data timing control signal DCS from the driving circuit unit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

The plurality of pixels PX, the plurality of data lines DL, a plurality of scan lines GWL, GCL, and GBL, and a plurality of emission control lines EL may be disposed the display area DAA of the display unit 200. The plurality of scan lines may include the first scan lines GWL, the second scan lines GCL, and the third scan lines GBL. The plurality of scan lines GWL, GCL, and GBL and the plurality of emission control lines EL1 and EL2 may extend in the first direction DR1 and may be arranged to be spaced (e.g., spaced apart) from each other in the second direction DR2. The plurality of data lines DL may extend in the second direction DR2 and may be arranged to be spaced (e.g., spaced apart) from each other in the first direction DR1.

FIG. 6 is an equivalent circuit diagram of one sub-pixel according to one or more embodiments.

Referring to FIG. 6, a sub-pixel SP1 may be connected to a first scan line GWL, a second scan line GCL, a third scan line GBL, a first emission control line EL1, a second emission control line EL2, and a data line DL. In addition, the sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The sub-pixel SP1 includes a plurality of transistors T1 to T6, a light emitting element LE, a first capacitor C1, and a second capacitor C2.

The light emitting element LE emits light according to a driving current Ids flowing through a channel of a first transistor T1. An amount of light emitted from the light emitting element LE may be proportional to the driving current Ids. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but is not limited thereto. For example, the light emitting element LE may be an inorganic light emitting element including a first electrode, a second electrode, and an inorganic semiconductor disposed between the first electrode and the second electrode, and in this case, the light emitting element LE may be a micro light emitting diode.

The first transistor T1 may be a driving transistor controlling a source-drain current Ids (hereinafter referred to as a “driving current”) flowing between a source electrode and a drain electrode according to a voltage applied to a gate electrode thereof. The first transistor T1 includes the gate electrode connected to a first node N1, the source electrode connected to a drain electrode of a sixth transistor T6, and the drain electrode connected to a second node N2.

A second transistor T2 may be disposed between one electrode of the first capacitor C1 and the data line DL. The second transistor T2 is turned on by a write scan signal of the first scan line GWL to connect one electrode of the first capacitor C1 to the data line DL. For this reason, a data voltage of the data line DL may be applied to one electrode of the first capacitor C1. The second transistor T2 includes a gate electrode connected to the first scan line GWL, a source electrode connected to the data line DL, and a drain electrode connected to one electrode of the first capacitor C1.

A third transistor T3 may be disposed between the first node N1 and the second node N2. The third transistor T3 is turned on by a control scan signal of the second scan line GCL to connect the first node N1 to the second node N2. For this reason, the gate electrode and the drain electrode of the first transistor T1 are connected to each other, and thus, the first transistor T1 may operate like a diode (e.g., the first transistor T1 may be diode-connected). The third transistor T3 includes a gate electrode connected to the second scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. For this reason, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 is turned on by a bias scan signal of the third scan line GBL to connect the third node N3 to the third driving voltage line VIL. For this reason, the third driving voltage VINT of the third driving voltage line VIL may be applied to the first electrode of the light emitting element LE. The fifth transistor T5 includes a gate electrode connected to the third scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor C1, and one electrode of the second capacitor C2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but is not limited thereto. Each of the first to sixth transistors T1 to T6 may be an N-type MOSFET. Alternatively, some of the first to sixth transistors T1 to T6 may be P-type MOSFETs, and the others of the first to sixth transistors T1 to T6 may be N-type MOSFETs.

It has been illustrated in FIG. 6 that the sub-pixel SP1 includes six transistors T1 to T6 and two capacitors C1 and C2, but it is to be noted that an equivalent circuit diagram of the sub-pixel SP1 is not limited to that illustrated in FIG. 6. For example, the numbers of transistors and capacitors of the sub-pixel SP1 are not limited to those illustrated in FIG. 6.

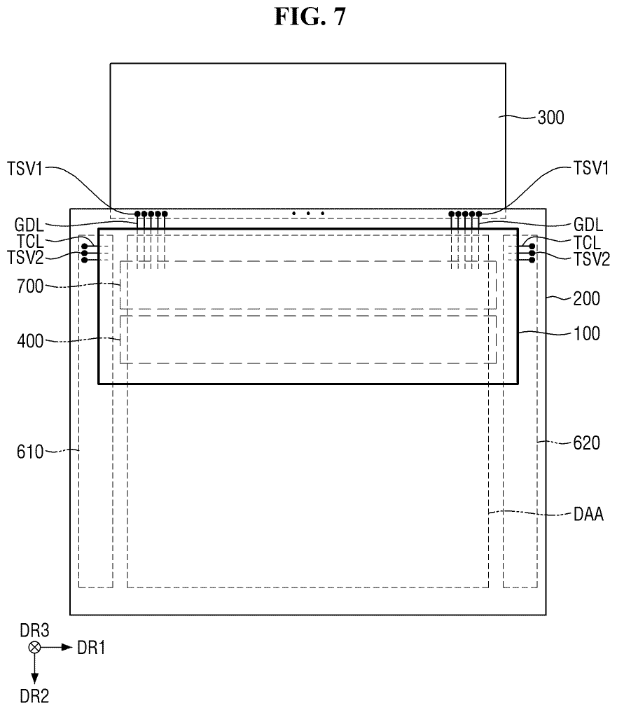

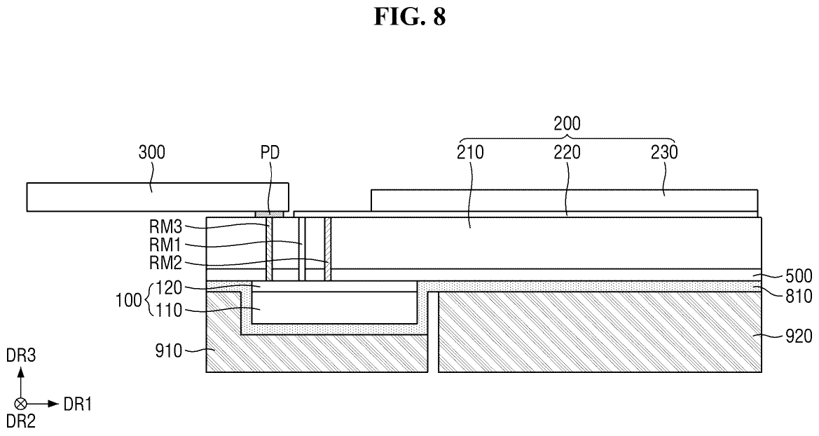

FIG. 7 is a schematic view illustrating a rear surface of the display device according to one or more embodiments. FIG. 8 is a schematic cross-sectional view of the display device according to one or more embodiments. FIG. 8 illustrates a schematic arrangement of routing lines RM1, RM2, and RM3 electrically connecting the display unit 200 and the driving unit 100 to each other, and FIG. 7 illustrates an arrangement of the first through holes TSV1 and the second through holes TSV2 as viewed from a rear surface of the display device 10.

Referring to FIGS. 7 and 8 in conjunction with FIG. 4, the display device 10 according to one or more embodiments may include a driving unit 100 including a first single crystal semiconductor substrate 110 and a driving circuit layer 120 disposed on the first single crystal semiconductor substrate 110, and a display unit 200 including a second single crystal semiconductor substrate 210 and a pixel circuit unit 220 and a display element layer 230 that are disposed on the second single crystal semiconductor substrate 210. The display device 10 may include two different single crystal semiconductor substrates 110 and 210 overlapping each other in the third direction DR3, which is the thickness direction of the display device 10.

The driving unit 100 may include circuit elements necessary for light emitting elements included in the display element layer 230 of the display unit 200 to emit light. As described above, the driving circuit layer 120 of the driving unit 100 may include the driving circuit unit 400, the data driver 700, and/or the like, and circuit elements such as transistors and capacitors constituting the driving circuit unit 400, the data driver 700, and/or the like, may be formed as CMOSs on the first single crystal semiconductor substrate 110.

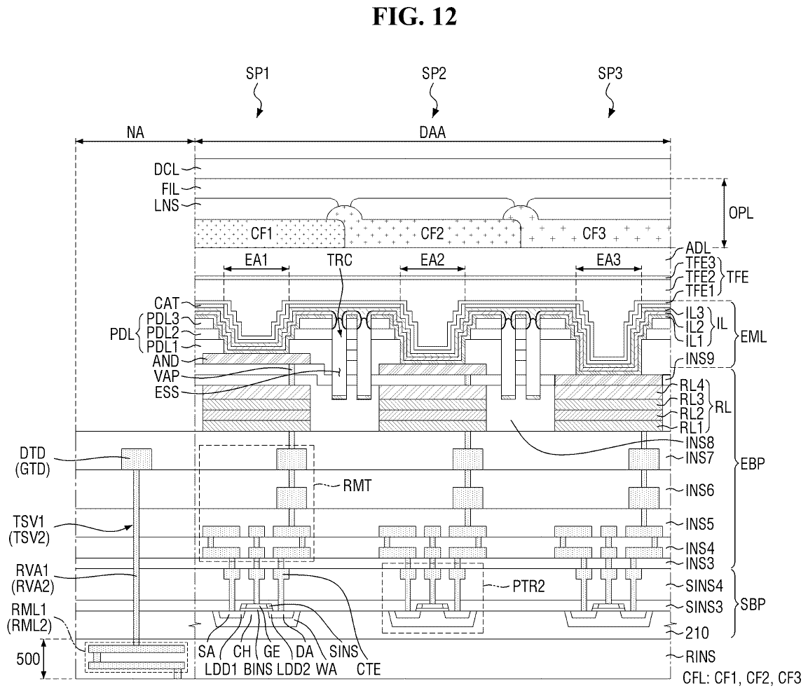

The display unit 200 may include a plurality of light emitting elements emitting light so as to display an image of the display device 10. The light emitting elements may be electrically connected to the circuit elements formed in the driving unit 100 and emit the light. In addition, the display unit 200 may include the pixel circuit unit 220 in which circuit elements constituting pixel circuits electrically connected to the respective sub-pixels SP1, SP2, and SP3, a plurality of lines, and the gate drivers 610 and 620 are disposed. The pixel circuit unit 220 may include circuit elements constituting the pixel circuit, such as the first to sixth transistors T1 to T6 of FIG. 6, scan transistors constituting the gate drivers 610 and 620, and a plurality of scan lines GL and data lines DL. In addition, the pixel circuit unit 220 may include a plurality of terminals DTD and GTD (see FIG. 12) connected to the through holes TSV1, TSV2, and TSV3 disposed in the non-display area NA of the display unit 200.

According to one or more embodiments, in the display device 10, an area of the driving unit 100 or the first single crystal semiconductor substrate 110 in a plan view may be smaller than an area of the display unit 200 or the second single crystal semiconductor substrate 210 in a plan view. A plurality of transistors formed in the driving unit 100 may be formed through a semiconductor fine process to have very small sizes or line widths. The driving unit 100 has an advantage that a large number of circuit elements may be disposed with a high degree of integration and power consumption is reduced due to miniaturization of the elements.

In addition, the driving unit 100 includes only the circuit elements formed as the CMOSs on the first single crystal semiconductor substrate 110 and does not include the light emitting elements, and thus, it may be sufficient for the driving unit 100 to secure only a space enough to dispose elements formed through a fine process. It may be sufficient for the first single crystal semiconductor substrate 110 to have a smaller area than the second single crystal semiconductor substrate 210, and a large number of driving units 100 may be manufactured on one wafer substrate on which a process of forming the driving circuit layer 120 is performed, such that a manufacturing yield of the driving unit 100 may be improved. In particular, the driving unit 100 is subjected to a high-cost semiconductor process, and thus, an effect of a cost reduction due to the improvement of the manufacturing yield of the driving unit 100 may be achieved. In addition, in the display unit 200, a large number of light emitting elements may be formed on the second single crystal semiconductor substrate 210 having a relatively great area, such that a high-resolution display device may be implemented.

The display device 10 may include a connection line layer 500 disposed between the second single crystal semiconductor substrate 210 of the display unit 200 and the driving circuit layer 120 of the driving unit 100. The connection line layer 500 may be disposed on a lower surface of the second single crystal semiconductor substrate 210. The connection line layer 500 may include a plurality of routing lines RM1, RM2, and RM3, and the routing lines RM (e.g., RM1, RM2, and RM3) may connect the pixel circuit unit 220 and the circuit board 300 disposed on the display unit 200 to the driving unit 100. The driving circuit layer 120 of the driving unit 100 may be electrically connected to the display unit 200 and the circuit board 300 through the routing lines RM1, RM2, and RM3 of the connection line layer 500 to transfer electrical signals for light emission.

First routing lines RM1 may be connected to the data lines DL disposed in the display unit 200 and the data driver 700 disposed in the driving unit 100. The first routing lines RM1 may be disposed in the first through holes TSV1 formed in the second single crystal semiconductor substrate 210, and may include data routing lines GDL of the connection line layer 500. A plurality of first through holes TSV1 may be disposed in the non-display area NA of the display unit 200, and may not overlap the driving unit 100 in the thickness direction (e.g., the third direction DR3).

The plurality of first through holes TSV1 may be disposed in the second pad area PDA2 of the non-display area NA of the display unit 200, and may not overlap the driving unit 100 in the thickness direction, but ma overlap the circuit board 300 in the thickness direction (e.g., the third direction DR3). The first routing lines RM1 may be partially disposed in the first through holes TSV1, and the data routing lines GDL may be disposed in the connection line layer 500 and may connect the first through holes TSV1 that do not overlap the driving unit 100 and the data driver 700 to each other. The driving unit 100 disposed on a rear surface of the display unit 200 may not partially overlap the non-display area NA of the display unit 200. The driving unit 100 may not overlap the through holes TSV1, TSV2, and TSV3 disposed in the non-display area NA.

According to one or more embodiments, the number of first through holes TSV1 may be the same as the number of pixel columns of the plurality of sub-pixels SP1, SP2, and SP3 disposed in the display area DAA. For example, the plurality of sub-pixels SP1, SP2, and SP3 may be arranged along the first direction DR1 and the second direction DR2 in the display area DAA, and when the number of pixel columns arranged along the first direction DR1 is 4000, the number of first through holes TSV1 may also be 4000, which is the same as the number of pixel columns arranged along the first direction DR1. The first through holes TSV1 may correspond to the pixel columns of the sub-pixels SP1, SP2, and SP3 arranged along the first direction DR1 in a one-to-one manner, and may also correspond to the plurality of data lines DL and the first routing lines RM1 arranged along the first direction DR1 in a one-to-one manner. One data line DL disposed in parallel with one pixel column may be connected to the data driver 700 through the first routing line RM1 disposed in one first through hole TSV1. The number of first routing lines RM1 and the number of first through holes TSV1 may be the same as the number of pixel columns and the number of data lines DL.

The plurality of data lines DL may extend in the second direction DR2 and may be respectively connected to the first through holes TSV1 in parallel with each other without being bent even in the non-display area NA. In the display device 10, an interval between the data lines DL may be kept constant in the display area DAA and the non-display area NA of the display unit 200, and a fan-out structure in which the data lines DL are bent and narrow in the non-display area NA may be omitted. Intervals between the first through holes TSV1 and the data routing line GDL spaced (e.g., spaced apart) from each other may also be kept constant, similar to the interval between the data lines DL. The driving unit 100 of the display device 10 may have a width enough for the data lines DL and the data routing lines GDL spaced (e.g., spaced apart) from each other at equal intervals to be disposed to extend in parallel with each other. For example, a width of the driving unit 100 of the display device 10 measured in the first direction DR1 may be greater than a width of the display area DAA measured in the first direction DR1. In the display device 10, the data lines DL may be connected to the driving unit 100 through the first through holes TSV1 and may be disposed in parallel with each other without the fan-out structure, and interference between other adjacent lines may be reduced or minimized.

Second routing lines RM2 may be connected to the gate drivers 610 and 620 disposed in the display unit 200 and the driving circuit unit 400 disposed in the driving unit 100. The second routing lines RM2 may be disposed in the second through holes TSV2 formed in the second single crystal semiconductor substrate 210, and may include control routing lines TCL of the connection line layer 500. A plurality of second through holes TSV2 may be disposed in the non-display area NA of the display unit 200, and may not overlap the driving unit 100 and the circuit board 300 in the thickness direction (e.g., the third direction DR3). In one or more embodiments, the plurality of second through holes TSV2 may be disposed to overlap the scan driver 610 and the emission driver 620, respectively.

The second routing lines RM2 may be partially disposed in the second through holes TSV2, and the control routing lines TCL may be disposed in the connection line layer 500 and may connect the second through holes TSV2 that do not overlap the driving unit 100 and the driving unit 100 to each other.

The gate drivers 610 and 620 may be electrically connected to the driving circuit unit 400 of the driving unit 100 and may receive timing control signals. Unlike the first through holes TSV1 and the first routing lines RM1, the second through holes TSV2 and the second routing lines RM2 may not be disposed to correspond to the scan lines GL in a one-to-one manner. In one or more embodiments, the numbers of second through holes TSV2 and second routing lines RM2 may be smaller than the numbers of first through holes TSV1 and first routing lines RM1, respectively.

Third routing lines RM3 may be connected to the second pads PD2 disposed in the display unit 200 and the first pad PD1 disposed in the driving unit 100. The third routing lines RM3 may be disposed in the third through holes TSV3 formed in the second single crystal semiconductor substrate 210. The third through holes TSV3 may be disposed to overlap the second pads PD2 and the circuit board 300 in the second pad area PDA2, and the third routing lines RM3 may be partially disposed in the connection line layer 500 and may be disposed to overlap the driving unit 100. The third routing lines RM3 may be lines transferring signals applied from the circuit board 300 to the driving unit 100.

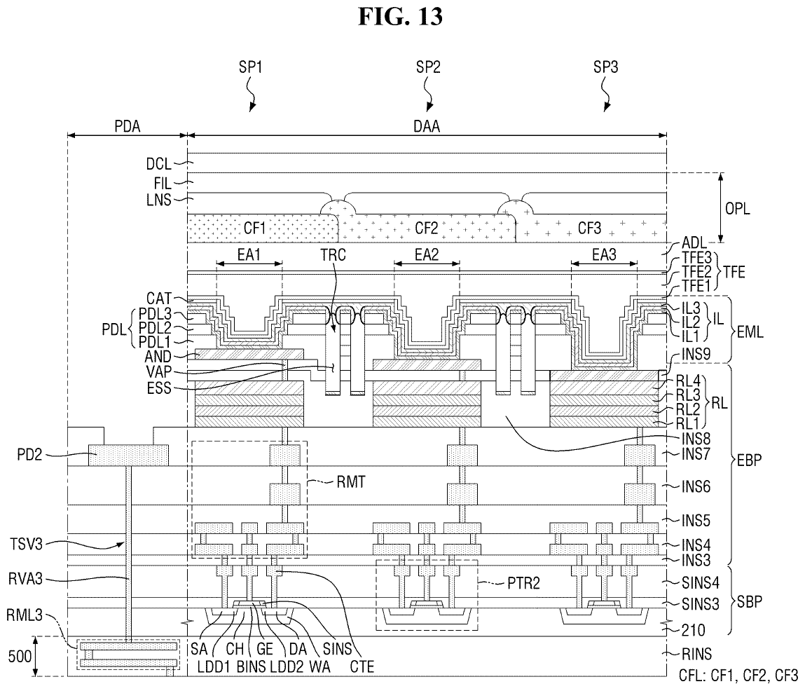

The routing lines RM1, RM2, and RM3 may include, respectively, connection lines RML1, RML2, and RML3 (see FIGS. 12 and 13) disposed in the connection line layer 500 and conductive vias RVA1, RVA2, and RVA3 (see FIGS. 12 and 13) disposed in the through holes TSV1, TSV2, and TSV3 of the second single crystal semiconductor substrate 210. The routing lines RM1, RM2, and RM3 are lines electrically connecting layers disposed above and below the second single crystal semiconductor substrate 210 to each other, and an arrangement and a design of the through holes formed in the second single crystal semiconductor substrate 210 may be changed depending on an arrangement of layers electrically connected to the routing lines RM.

The heat dissipation member HTM may include a heat dissipation layer 810 disposed on rear surfaces of the driving unit 100 and the display unit 200 and a plurality of heat dissipation substrates 910 and 920 disposed below the heat dissipation layer 810.

The heat dissipation layer 810 may be disposed around the driving unit 100. The heat dissipation layer 810 may be around (e.g., may surround) the driving unit 100 and may be disposed on the lower surface of the display unit 200. For example, the heat dissipation layer 810 may be in contact with and may be around (e.g., may surround) each of the lower surface and side surfaces of the driving unit 100, and may extend around the driving unit 100 to cover the entirety of a portion of the lower surface of the display unit 200 that does not overlap the driving unit 100. The heat dissipation layer 810 may be in direct contact with the first single crystal semiconductor substrate 110 of the driving unit 100, and may be in direct contact with the connection line layer 500 disposed below the second single crystal semiconductor substrate 210. In addition, the heat dissipation layer 810 may overlap each of the driving circuit layer 120 of the driving unit 100 and the pixel circuit unit 220 and display element layer 230 of the display unit 200.

The heat dissipation layer 810 may include a material having high thermal conductivity so as to effectively transfer heat generated from the driving unit 100 and the display unit 200 to the heat dissipation substrates 910 and 920. The heat dissipation layer 810 may include a material having higher thermal conductivity than the single crystal semiconductor substrates 110 and 210 with which it is in direct contact, and the heat generated from the driving unit 100 and the display unit 200 may be transferred to the heat dissipation layer 810 rather than the single crystal semiconductor substrates 110 and 210. For example, the heat dissipation layer 810 may include a metal material having high thermal conductivity, such as tungsten (W), aluminum (AI), and/or copper (Cu) and/or inorganic particles having high thermal conductivity, such as graphene and/or graphite.

The heat dissipation substrates 910 and 920 may be disposed below the heat dissipation layer 810. The heat dissipation substrates 910 and 920 may overlap the driving unit 100 and the display unit 200 and may dissipate the heat transferred to the heat dissipation layer 810 to the outside. As an example, the heat dissipation substrates 910 and 920 may include a first heat dissipation substrate 910 disposed to overlap the driving unit 100 and a second heat dissipation substrate 920 that does not overlap the driving unit 100 and is spaced (e.g., spaced apart) from the first heat dissipation substrate 910.

The first heat dissipation substrate 910 may be disposed to cover the driving unit 100 and the periphery of the driving unit 100. The first heat dissipation substrate 910 may be disposed to be biased to the other side in the first direction DR1 with respect to the center of the display unit 200, and may entirely overlap a portion where the driving unit 100 and the circuit board 300 are disposed. A portion of the first heat dissipation substrate 910 may overlap the driving unit 100, and the other portion of the first heat dissipation substrate 910 may overlap the display unit 200 exposed around the driving unit 100 and the circuit board 300 disposed above the display unit 200. In addition, the first heat dissipation substrate 910 may be around (e.g., may surround) the side surfaces of the driving unit 100.

The second heat dissipation substrate 920 may be spaced (e.g., spaced apart) from the first heat dissipation substrate 910, and may not overlap the driving unit 100. The second heat dissipation substrate 920 may be disposed to be biased to one side in the first direction DR1 with respect to the center of the display unit 200, and may overlap the display unit 200 that does not overlap the driving unit 100 and the circuit board 300. However, the present disclosure is not limited thereto, and the heat dissipation substrates 910 and 920 may not be divided into the first heat dissipation substrate 910 and the second heat dissipation substrate 920 and may be formed integrally with each other.

In one or more embodiments, respective side surfaces of the first heat dissipation substrate 910 and the second heat dissipation substrate 920 may be parallel to side surfaces of the display unit 200. The first heat dissipation substrate 910 and the second heat dissipation substrate 920 may fill a step between the driving unit 100 and the display unit 200. However, the present disclosure is not limited thereto.

The heat dissipation substrates 910 and 920 may include a material having high thermal conductivity to effectively dissipate heat generated from the driving unit 100, the display unit 200, and the circuit board 300. For example, the heat dissipation substrates 910 and 920 may be made of a metal material having high thermal conductivity, such as tungsten (W), aluminum (AI), and/or copper (Cu).

The display device 10 may include the different single crystal semiconductor substrates 110 and 210 respectively included in the driving unit 100 and the display unit 200, and may include the plurality of routing lines RM1, RM2, and RM3 connecting the different single crystal semiconductor substrates 110 and 210 to each other. The routing lines RM1, RM2, and RM3 may be respectively disposed in the through holes TSV1, TSV2, and TSV3 formed in the second single crystal semiconductor substrate 210, and may transfer electrical signals for driving the display device 10. The routing lines RM1, RM2, and RM3 are intensively disposed in a partial area of the display device 10, and accordingly, a lot of heat may be generated in the driving unit 100, the display unit 200, and the circuit board 300 around the through holes TSV1, TSV2, and TSV3 when the display device 10 is driven. The display device 10 according to one or more embodiments may effectively dissipate the heat by including the heat dissipation layer 810 and the heat dissipation substrates 910 and 920 as the heat dissipation member HTM disposed around the driving unit 100.

Hereinafter, structures of the driving circuit layer 120 of the driving unit 100 and the display element layer 230 of the display unit 200 will be described in detail with further reference to other drawings.

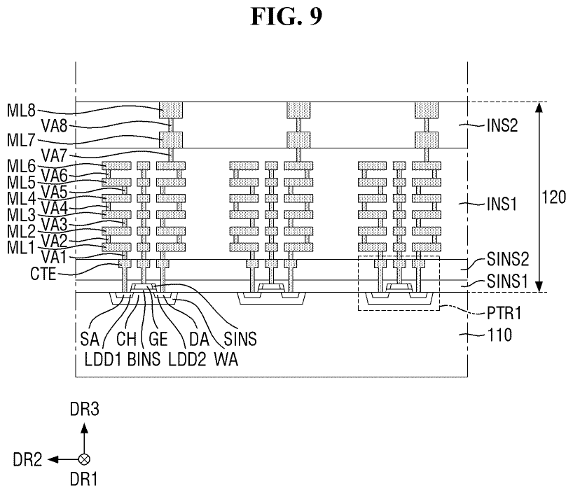

FIG. 9 is a schematic cross-sectional view of the driving unit according to one or more embodiments.

Referring to FIG. 9, the driving unit 100 may include a first single crystal semiconductor substrate 110 and a driving circuit layer 120 disposed on the first single crystal semiconductor substrate 110. FIG. 9 schematically illustrates a cross-sectional structure of the data driver 700 of circuit units disposed in the driving unit 100.

The first single crystal semiconductor substrate 110 may be a silicon substrate, a germanium substrate, and/or a silicon-germanium substrate. The first single crystal semiconductor substrate 110 may be a substrate doped with first-type impurities. A plurality of well regions WA may be disposed in an upper surface of the first single crystal semiconductor substrate 110. The plurality of well regions WA may be regions doped with second-type impurities. The second-type impurities may be different from the first-type impurities described above. For example, when the first-type impurities are P-type impurities, the second-type impurities may be N-type impurities. Alternatively, when the first-type impurities are N-type impurities, the second-type impurities may be P-type impurities.

Each of the plurality of well regions WA includes a source region SA corresponding to a source electrode of a first transistor PTR1, a drain region DA corresponding to a drain electrode of the first transistor PTR1, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. The gate electrode GE of the first transistor PTR1 may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA and a second low-concentration impurity region LDD2 disposed between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the first transistors PTR1 may increase, and thus, punch-through and hot carrier phenomena caused by a short channel may be prevented.

The first single crystal semiconductor substrate 110 may include a plurality of first transistors PTR1 constituting a plurality of circuit elements of the driving unit 100. The first transistors PTR1 formed on the first single crystal semiconductor substrate 110 may constitute the driving circuit unit 400 or the data driver 700.

A process of reducing a thickness of the first single crystal semiconductor substrate 110 may be performed when the driving circuit layer 120 is formed on a silicon wafer substrate. The first single crystal semiconductor substrate 110 may have a smaller thickness than the wafer substrate on which a semiconductor process for forming the driving circuit layer 120 is performed. In some embodiments, the first single crystal semiconductor substrate 110 may have a thickness of 100 μm or less, for example, a thickness in the range of 80 μm to 100 μm.

The driving circuit layer 120 may include a first semiconductor insulating film SINS1, a second semiconductor insulating film SINS2, a plurality of contact electrodes CTE, a first interlayer insulating film INS1, a second interlayer insulating film INS2, a plurality of conductive layers ML1 to ML8, and a plurality of vias VA1 to VA8. The driving circuit layer 120 may include lines electrically connected to the plurality of first transistors PTR1 included in the first single crystal semiconductor substrate 110.

The first semiconductor insulating film SINS1 and the second semiconductor insulating film SINS2 may be disposed on the first single crystal semiconductor substrate 110. The first semiconductor insulating film SINS1 may be an insulating film disposed on the first single crystal semiconductor substrate 110, and the second semiconductor insulating film SINS2 may be an insulating film disposed on the gate electrode GE of the first transistor PTR1 and the first semiconductor insulating film SINS1. The first semiconductor insulating film SINS1 and the second semiconductor insulating film SINS2 may each be formed as a silicon carbonitride (SiCN) and/or silicon oxide (SiOₓ)-based inorganic film, but are not limited thereto. It has been illustrated in FIG. 9 that the first semiconductor insulating film SINS1 and the second semiconductor insulating film SINS2 are each formed as a single layer having a suitable thickness (e.g., a predetermined thickness), but the present disclosure is not limited thereto. The first semiconductor insulating film SINS1 and the second semiconductor insulating film SINS2 may also have a structure in which one or more layers are stacked.

The plurality of contact electrodes CTE may be disposed on the first single crystal semiconductor substrate 110. Each of the plurality of contact electrodes CTE may be connected to one of the gate electrode GE, the source region SA, and the drain region DA of each of the first transistors PTR1 formed on the first single crystal semiconductor substrate 110 through a hole penetrating through the semiconductor insulating films SINS1 and SINS2. Each of the plurality of contact electrodes CTE may be made of copper (Cu), aluminum (AI), tungsten (W), molybdenum (Mo), chromium (Cr), gold (Au), titanium (Ti), nickel (Ni), and/or neodymium (Nd), and/or alloys thereof. Upper surfaces of the plurality of contact electrodes CTE may be exposed without being covered by the semiconductor insulating films SINS1 and SINS2.

The first interlayer insulating film INS1 may be disposed on the plurality of contact electrodes CTE and the semiconductor insulating films SINS1 and SINS2. The second interlayer insulating film INS2 may be disposed on the first interlayer insulating film INS1. The first interlayer insulating film INS1 and the second interlayer insulating film INS2 may each be formed as a silicon carbonitride (SiCN) and/or silicon oxide (SiOₓ)-based inorganic film, but are not limited thereto. It has been illustrated in FIG. 9 that the first interlayer insulating film INS1 and the second interlayer insulating film INS2 are each formed as a single layer, but the present disclosure is not limited thereto. The first interlayer insulating film INS1 and the second interlayer insulating film INS2 may each have a structure in which one or more layers are stacked, and may be disposed between a plurality of first to eighth conductive layers ML1 to ML8 to be described later.

First to eighth conductive layers ML1 to ML8 and first to eighth vias VA1 to VA8 may be electrically connected to the plurality of contact electrodes CTE, and may form the driving circuit unit 400 or the data driver 700 of the driving unit 100. The plurality of first transistors PTR1 formed on the first single crystal semiconductor substrate 110 may be electrically connected to each other through the first to eighth conductive layers ML1 to ML8 and the first to eighth vias VA1 to VA8, and may form the driving circuit unit 400 and the data driver 700 of the driving unit 100.

The first conductive layers ML1 may be connected to the contact electrodes CTE through the first vias VA1. The first conductive layers ML1 may be disposed on the contact electrodes CTE, and the first vias VA1 may be disposed between the first conductive layers ML1 and the contact electrodes CTE and in contact with each of the first conductive layers ML1 and the contact electrodes CTE. The second conductive layers ML2 may be connected to the first conductive layers ML1 through the second vias VA2. The second conductive layers ML2 may be disposed on the first conductive layers ML1, and the second vias VA2 may be disposed between the first conductive layers ML1 and the second conductive layers ML2 and in contact with each of the first conductive layers ML1 and the second conductive layers ML2.

The third conductive layers ML3 may be connected to the second conductive layers ML2 through the third vias VA3. The fourth conductive layers ML4 may be connected to the third conductive layers ML3 through the fourth vias VA4, the fifth conductive layers ML5 may be connected to the fourth conductive layers ML4 through the fifth vias VA5, and the sixth conductive layers ML6 may be connected to the fifth conductive layers ML5 through the sixth vias VA6. The third conductive layers ML3, the fourth conductive layers ML4, the fifth conductive layers ML5, and the sixth conductive layers ML6 may be sequentially disposed on the second conductive layers ML2, and the third vias VA3, the fourth vias VA4, the fifth vias VA5, and the sixth vias VA6 may be disposed between the third conductive layers ML3, the fourth conductive layers ML4, the fifth conductive layers ML5, and the sixth conductive layers ML6. The third to sixth vias VA3 to VA6 may be in contact with different conductive layers disposed above and below the first to sixth vias VA3 to VA6, respectively. The seventh vias VA7 may be disposed on the sixth conductive layers ML6. The seventh vias VA7 may be in contact with the seventh conductive layers ML7 and the sixth conductive layers ML6 disposed above and below the seventh vias VA7, respectively.

The first to sixth conductive layers ML1 to ML6 and the first to seventh vias VA1 to VA7 may be disposed in the first interlayer insulating film INS1. The first to sixth conductive layers ML1 to ML6 and the first to seventh vias VA1 to VA7 may constitute a first driving circuit layer disposed in the first interlayer insulating film INS1 of the driving circuit layer 120.

The seventh conductive layers ML7 may be connected to the sixth conductive layers ML6 through the seventh vias VA7. The seventh conductive layers ML7 may be disposed on the first interlayer insulating film INS1 and the sixth conductive layers ML6, and the seventh vias VA7 may be disposed on the sixth conductive layers ML6 and the seventh conductive layers ML7 and in contact with each of the sixth conductive layers ML6 and the seventh conductive layers ML7. The eighth conductive layers ML8 may be connected to the seventh conductive layers ML7 through the eighth vias VA8. The eighth conductive layers ML8 may be disposed on the seventh conductive layers ML7, and the eighth vias VA8 may be disposed between the seventh conductive layer ML7 and the eighth conductive layer ML8 and in contact with each of the seventh conductive layer ML7 and the eighth conductive layer ML8. Upper surfaces of the eighth conductive layers ML8 may be exposed without being covered by the second interlayer insulating film INS2, and may be electrically connected to the routing lines RM disposed in the display unit 200 described above.

The seventh conductive layers ML7, the eighth vias VA8, and the eighth conductive layers ML8 may be disposed in the second interlayer insulating film INS2. The seventh conductive layers ML7, the eighth vias VA8, and the eighth conductive layers ML8 may constitute a second driving circuit layer disposed in the second interlayer insulating film INS2 of the driving circuit layer 120.

It has been illustrated in FIG. 9 that the first to eighth conductive layers ML1 to ML8 and the first to eighth vias VA1 to VA8 are sequentially stacked, but an arrangement and connection of the first to eighth conductive layers ML1 to ML8 and the first to eighth vias VA1 to VA8 may be variously changed depending on circuits of the driving circuit unit 400 and the data driver 700 of the driving unit 100. A connection structure illustrated in FIG. 9 is only an example, and connection of the driving circuit layer 120 disposed in the driving unit 100 of the display device 10 is not limited thereto. In addition, the driving circuit layer 120 may not necessarily include the first to eighth conductive layers ML1 to ML8 and the first to eighth vias VA1 to VA8, and some of the first to eighth conductive layers ML1 to ML8 and the first to eighth vias VA1 to VA8 may be omitted or larger numbers of conductive layers and vias may be disposed.

The first to eighth conductive layers ML1 to ML8 and the first to eighth vias VA1 to VA8 may be made of substantially the same material. For example, each of the first to eighth conductive layers ML1 to ML8 and the first to eighth vias VA1 to VA8 may be made of copper (Cu), aluminum (AI), tungsten (W), molybdenum (Mo), chromium (Cr), gold (Au), titanium (Ti), nickel (Ni), and/or neodymium (Nd), and/or alloys thereof.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the thickness of the eighth conductive layer ML8 may be approximately 9000 Å. Each of the thickness of the seventh via VA7 and the thickness of the eighth via VA8 may be approximately 6000 Å.

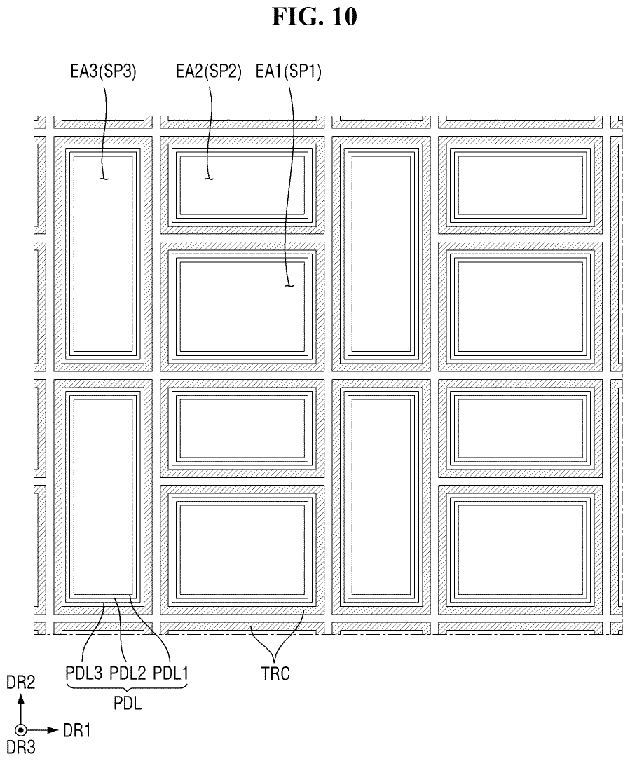

FIG. 10 is a plan view illustrating first electrodes and emission areas of a plurality of sub-pixels and a pixel defining film that are disposed in a display area of the display unit according to one or more embodiments.

Referring to FIG. 10, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include a first emission area EA1, the second sub-pixel SP2 may include a second emission area EA2, and the third sub-pixel SP3 may include a third emission area EA3.

Each of the first emission area EA1, the second emission area EA2, and the third emission area EA3 may have a quadrangular shape such as a rectangular shape, a square shape, or a rhombic shape in a plan view. For example, the third emission area EA3 may have a rectangular shape, in a plan view, having short sides extending in the first direction DR1 and long sides extending in the second direction DR2. In addition, each of the second emission area EA2 and the first emission area EA1 may have a rectangular shape, in a plan view, having long sides extending in the first direction DR1 and short sides extending in the second direction DR2.

Each of the first emission area EA1, the second emission area EA2, and the third emission area EA3 may be an area defined by a pixel defining film PDL. For example, each of the first emission area EA1, the second emission area EA2, and the third emission area EA3 may be an area defined by a first pixel defining film PDL1.

A length of the third emission area EA3 in the first direction DR1 may be smaller than a length of the first emission area EA1 in the first direction DR1 and smaller than a length of the second emission area EA2 in the first direction DR1. The length of the first emission area EA1 in the first direction DR1 and the length of the second emission area EA2 in the first direction DR1 may be substantially the same as each other.

In each of the plurality of pixels PX, the first emission area EA1 and the second emission area EA2 may neighbor to each other in the second direction DR2. In addition, the first emission area EA1 and the third emission area EA3 may neighbor to each other in the first direction DR1. In addition, the second emission area EA2 and the third emission area EA3 may neighbor to each other in the first direction DR1. An area of the first emission area EA1, an area of the second emission area EA2, and an area of the third emission area EA3 may be different from each other.

It has been illustrated in FIG. 10 that each of the first emission area EA1, the second emission area EA2, and the third emission area EA3 has the quadrangular shape in a plan view, but the present disclosure is not limited thereto. For example, each of the first emission area EA1, the second emission area EA2, and the third emission area EA3 may have other polygonal shapes other than the quadrangular shape, a circular shape, and/or an elliptical shape in a plan view.

The first emission area EA1 may emit a first light, the second emission area EA2 may emit a second light, and the third emission area EA3 may emit a third light. Here, the first light may be light of a red wavelength band, the second light may be light of a green wavelength band, and the third light may be light of a blue wavelength band. For example, the blue wavelength band may indicate that a main peak wavelength of the light is included in a wavelength band of approximately 370 nm to 460 nm, the green wavelength band may indicate that a main peak wavelength of the light is included in a wavelength band of approximately 480 nm to 560 nm, and the red wavelength band may indicate that a main peak wavelength of the light is included in a wavelength band of approximately 600 nm and 750 nm.

A first electrode AND of the light emitting element may have a rectangular shape in a plan view. The shape of the first electrode AND of the light emitting element in a plan view may be different in the first sub-pixel SP1, the second sub-pixel SP2, and the third sub-pixel SP3. For example, each of the first electrode AND of the first sub-pixel SP1 and the first electrode AND of the second sub-pixel SP2 may have a rectangular shape, in a plan view, having long sides in the first direction DR1 and short sides in the second direction DR2. The first electrode AND of the third sub-pixel SP3 may have a rectangular shape, in a plan view, having short sides in the first direction DR1 and long sides in the second direction DR2. A length of the first electrode AND of the third sub-pixel SP3 in the first direction DR1 may be smaller than a length of the first electrode AND of each of the first sub-pixel SP1 and the second sub-pixel SP2 in the first direction DR1. A length of the first electrode AND of the first sub-pixel SP1 in the second direction DR2 may be greater than a length of the first electrode AND of the second sub-pixel SP2 in the second direction DR2.

The first electrode AND of the light emitting element may be connected to a reflective electrode layer RL (see FIG. 12) through an electrode via VAP. The electrode via VAP may overlap the first pixel defining film PDL1, a second pixel defining film PDL2, and a third pixel defining film PDL3 in the third direction DR3.

At least one trench TRC may be a structure for disconnecting at least one charge generation layer of a light emitting stack IL between the emission areas EA1, EA2, and EA3 neighboring each other. At least one trench TRC may be disposed between the first emission area EA1 and the second emission area EA2, between the first emission area EA1 and the third emission area EA3, and between the second emission area EA2 and the third emission area EA3. More specifically, at least one trench TRC may be disposed between the first electrode AND of the first sub-pixel SP1 and the first electrode AND of the second sub-pixel SP2, between the first electrode AND of the first sub-pixel SP1 and the first electrode AND of the third sub-pixel SP3, and between the first electrode AND of the second sub-pixel SP2 and the first electrode AND of the third sub-pixel SP3.

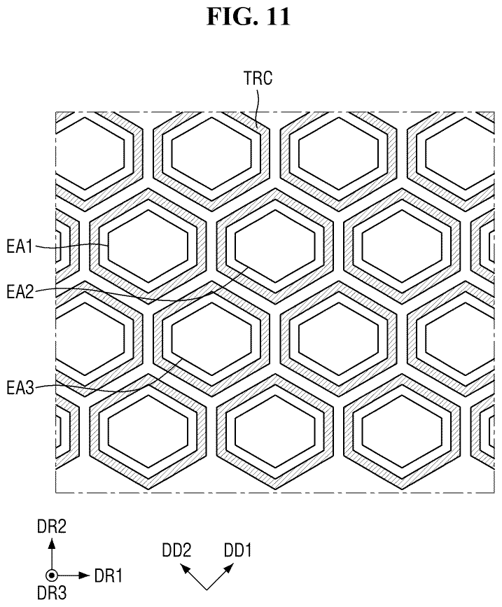

FIG. 11 is a plan view illustrating first electrodes and emission areas of a plurality of sub-pixels and a pixel defining film that are disposed in a display area of a display unit according to one or more embodiments.

Referring to FIG. 11, the present embodiment is substantially the same as an embodiment of FIG. 10 except for shapes of a first emission area EA1, a second emission area EA2, and a third emission area EA3 in a plan view, and a description overlapping the description of an embodiment of FIG. 10 is thus omitted.

The first emission area EA1, the second emission area EA2, and the third emission area EA3 may be disposed in a hexagonal structure having a hexagonal shape in a plan view. In this case, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1.

It has been illustrated in FIGS. 10 and 11 that each of the plurality of pixels PX includes three emission areas EA1, EA2, and EA3, but the present disclosure is not limited thereto. That is, each of the plurality of pixels PX may also include four emission areas.

In addition, an arrangement of the emission areas of the plurality of pixels PX is not limited to those illustrated in FIGS. 10 and 11. For example, the emission areas of the plurality of pixels PX may be disposed in a stripe structure in which the emission areas are arranged along the first direction DR1, a PENTILE® structure in which the emission areas have a diamond arrangement, or a hexagonal structure in which emission areas having a hexagonal shape in a plan view are arranged. PENTILE® are registered trademarks of Samsung Display Co., Ltd., Republic of Korea.

FIGS. 12 and 13 are cross-sectional views illustrating the display area and a portion of a non-display area of the display unit according to one or more embodiments. FIGS. 12 and 13 illustrate a schematic cross-sectional structure of the display area DAA, the non-display area NA, and the pad area PDA.

Referring to FIGS. 12 and 13, the display unit 200 may include a semiconductor backplane SBP, a light emitting element backplane EBP, a light emitting element layer EML, an encapsulation layer TFE, an adhesive layer ADL, a color filter layer CFL, a lens LNS, a filling layer FIL, and a cover layer DCL. In one or more embodiments, the display unit 200 may further include a polarizing plate disposed on the cover layer DCL. The connection line layer 500 may be disposed between a second single crystal semiconductor substrate 210 of the semiconductor backplane SBP and the first single crystal semiconductor substrate 110. Alternatively, the connection line layer 500 may be disposed between the light emitting element layer EML and the first single crystal semiconductor substrate 110.

The semiconductor backplane SBP may include a second single crystal semiconductor substrate 210 including a plurality of second transistors PTR2, a plurality of semiconductor insulating films disposed on the plurality of second transistors PTR2, and a plurality of contact electrodes CTE electrically connected to the plurality of second transistors, respectively. The plurality of second transistors PTR2 may be the first to sixth transistors T1 to T6 constituting the pixel circuit of FIG. 6 or the scan transistors of the gate drivers 610 and 620.

The second single crystal semiconductor substrate 210 may be a silicon substrate, a germanium substrate, and/or a silicon-germanium substrate. The second single crystal semiconductor substrate 210 may be a substrate doped with first-type impurities. A plurality of well regions WA may be disposed in an upper surface of the second single crystal semiconductor substrate 210. The plurality of well regions WA may be regions doped with second-type impurities. The second-type impurities may be different from the first-type impurities described above. For example, when the first-type impurities are P-type impurities, the second-type impurities may be N-type impurities. Alternatively, when the first-type impurities are N-type impurities, the second-type impurities may be P-type impurities.

The second single crystal semiconductor substrate 210 may include the plurality of second transistors PTR2, similar to the first single crystal semiconductor substrate 110. A structure of the second transistor PTR2 may be the same as that of the first transistor PTR1, and a detailed description thereof is thus omitted.

In the display device 10, the first transistor PTR1 formed on the first single crystal semiconductor substrate 110 of the driving unit 100 and the second transistor PTR2 formed on the second single crystal semiconductor substrate 210 of the display unit 200 may be formed on different wafer substrates. According to one or more embodiments, in the display device 10, sizes, line widths, and/or the like, of the first transistor PTR1 formed on the first single crystal semiconductor substrate 110 and the second transistor PTR2 formed on the second single crystal semiconductor substrate 210 may be different from each other.

For example, in the display device 10, a minimum line width of the first transistor PTR1 formed on the first single crystal semiconductor substrate 110 may be smaller than a minimum line width of the second transistor PTR2 formed on the second single crystal semiconductor substrate 210. A semiconductor process performed on a first wafer substrate in order to form the first transistor PTR1 may be a process having higher resolution than a semiconductor process performed on a second wafer substrate in order to form the second transistor PTR2, and a size of an element such as a transistor manufactured according to the semiconductor process performed on the first wafer substrate may be smaller than a size of an element such as a transistor manufactured according to the semiconductor process performed on the second wafer substrate. In other words, the semiconductor process performed on the first wafer substrate may be a finer process than the semiconductor process performed on the second wafer substrate.

As described above, the first single crystal semiconductor substrate 110 of the driving unit 100 may have a smaller area than the second single crystal semiconductor substrate 210 of the display unit 200 in a plan view, and elements having a small size may be disposed with a high degree of integration on the first single crystal semiconductor substrate 110, such that power consumption may be reduced and a manufacturing yield of the driving unit 100 may be improved. On the other hand, the second single crystal semiconductor substrate 210 of the display unit 200 has a greater area than the first single crystal semiconductor substrate 110 in a plan view, and a process in which a line width is relatively great may be performed on the second single crystal semiconductor substrate 210. The second transistors PTR2 may be formed in a greater area when they are disposed on the second single crystal semiconductor substrate 210 than when they are formed on the first single crystal semiconductor substrate 110, and the second transistors PTR2 constituting the pixel circuit may not require a high degree of integration. Accordingly, the semiconductor process performed on the first wafer substrate may be performed as a high-cost process in which a line width is small, and the semiconductor process performed on the second wafer substrate may be performed as a low-cost process in which a line width is relatively great.

In one or more embodiments, lengths of channel regions CH of a plurality of transistors PTR1 and PTR2 may be different from each other, and a minimum line width or a length of the channel region CH of the first transistor PTR1 may be smaller than a minimum line width or a length of the channel region CH of the second transistor PTR2. The minimum line width or the length of the channel region CH of the first transistor PTR1 may be 100 nm or less or be in the range of 2 nm to 80 nm. The minimum line width or the length of the channel region CH of the second transistor PTR2 may be 100 nm or more or may be in the range of 100 nm to 5 μm.

The second single crystal semiconductor substrate 210 may include a plurality of through holes TSV1, TSV2, and TSV3 spaced (e.g., spaced apart) from each other. The through holes TSV1, TSV2, and TSV3 may penetrate from an upper surface of the second single crystal semiconductor substrate 210 to a lower surface of the second single crystal semiconductor substrate 210, and may also penetrate through a plurality of semiconductor insulating films SINS3 and SINS4 and interlayer insulating films INS3, INS4, and INS5 disposed on the second single crystal semiconductor substrate 210. Conductive vias RVA1, RVA2, and RVA3 of the routing lines RM1, RM2, and RM3 may be disposed in the through holes TSV1, TSV2, and TSV3. The through holes TSV1, TSV2, and TSV3 may form connection passages of the routing lines RM1, RM2, and RM3 electrically connecting the driving unit 100 and the pixel circuit unit 220 and the second pads PD2 of the display unit 200 to each other. In one or more embodiments, the through holes TSV1, TSV2, and TSV3 of the second single crystal semiconductor substrate 210 may be formed through a through silicon via (TSV) process of forming holes penetrating through the wafer substrate. Through the through holes TSV1, TSV2, and TSV3 formed in the second single crystal semiconductor substrate 210, the display element layer 230 and the driving unit 100 may be electrically connected to each other through the routing lines RM1, RM2, and RM3 without separate wires.

A process of reducing a thickness of the second single crystal semiconductor substrate 210 may be performed after the driving unit 100 is bonded onto a silicon wafer substrate. The second single crystal semiconductor substrate 210 may have a smaller thickness than the wafer substrate on which a process for forming conductive layers is performed. In one or more embodiments, the second single crystal semiconductor substrate 210 may have a thickness of 100 μm or less, for example, a thickness in the range of 80 μm to 100 μm.

The pixel circuit unit 220 may be disposed on the second single crystal semiconductor substrate 210. The pixel circuit unit 220 may include the semiconductor backplane SBP and a portion of the light emitting element backplane EBP.

A third semiconductor insulating film SINS3 may be disposed on the second single crystal semiconductor substrate 210 and the second transistors PTR2. The third semiconductor insulating film SINS3 may be formed as a silicon carbonitride (SiCN) and/or silicon oxide (SiOₓ)-based inorganic film, but is not limited thereto.

A fourth semiconductor insulating film SINS4 may be disposed on the third semiconductor insulating film SINS3. The fourth semiconductor insulating film SINS4 may be formed as a silicon oxide (SiOₓ)-based inorganic film, but is not limited thereto.

Each of the plurality of contact electrodes CTE may be connected to one of the gate electrode GE, the source region SA, and/or the drain region DA of each of the second transistors PTR2 through a hole penetrating through the third semiconductor insulating film SINS3 and the fourth semiconductor insulating film SINS4. Each of the plurality of contact electrodes CTE may be made of copper (Cu), aluminum (AI), tungsten (W), molybdenum (Mo), chromium (Cr), gold (Au), titanium (Ti), nickel (Ni), and/or neodymium (Nd), or alloys thereof.

The light emitting element backplane EBP may include third to seventh interlayer insulating films INS3, INS4, INS5, INS6, and INS7 and a plurality of routing conductive layers RMT. The routing conductive layer RMT may include lines electrically connected to the plurality of second transistors PTR2 formed on the second single crystal semiconductor substrate 210, a plurality of scan lines GL and data lines DL disposed in the display unit 200, and a plurality of terminals DTD and GDT. In one or more embodiments, the light emitting element backplane EBP may also include eighth insulating layer INS8 and a reflective electrode layer RL.

The third interlayer insulating film INS3 may be disposed on the plurality of contact electrodes CTE and the semiconductor insulating films SINS3 and SINS4. The fourth interlayer insulating film INS4 may be disposed on the third interlayer insulating film INS3. The fifth interlayer insulating film INS5, the sixth interlayer insulating film INS6, and the seventh interlayer insulating film INS7 may be sequentially disposed on the fourth interlayer insulating film INS4. The plurality of routing conductive layers RMT may be disposed between the third interlayer insulating film INS3 to the seventh interlayer insulating film INS7. The third interlayer insulating film INS3 to the seventh interlayer insulating film INS7 may each be formed as a silicon carbonitride (SiCN) and/or silicon oxide (SiOₓ)-based inorganic film, but are not limited thereto. It has been illustrated in FIGS. 12 and 13 that the third interlayer insulating film INS3 to the seventh interlayer insulating film INS7 are each formed as a single layer, but the present disclosure is not limited thereto. The third interlayer insulating film INS3 to the seventh interlayer insulating film INS7 may each have a structure in which one or more layers are stacked, and may be disposed between a plurality of first to eighth conductive layers ML1 to ML8 to be described later (e.g., also discussed with respect to FIG. 9).

The routing conductive layer RMT may have a similar structure to the plurality of conductive layers ML1 to ML8 and vias VA1 to VA8 of the driving circuit layer 120. The routing conductive layer RMT may constitute the lines or the terminals DTD and GTD disposed in the display unit 200 by including one or more conductive layers and vias disposed between the one or more conductive layers. For example, the routing conductive layers RMT of the pixel circuit unit 220 disposed in the display area DAA may be electrically connected to the second transistors PTR2. The routing conductive layers RMT illustrated in FIGS. 12 and 13 may be connected to the plurality of second transistors PTR2 to constitute the pixel circuit of FIG. 6. The routing conductive layers RMT may serve as connection lines connecting the second transistors PTR2 and other circuit elements to each other. In addition, in one or more embodiments, some of the routing conductive layers RMT of the pixel circuit unit 220 disposed in the display area DAA may be the scan lines GL or the data lines DL or may serve as connection lines constituting the gate drivers 610 and 620.

The pixel circuit unit 220 may include a plurality of terminals DTD and GTD disposed in the non-display area NA. The plurality of terminals DTD and GTD may include data terminals DTD electrically connected to the data lines DL and gate terminals GTD connected to the gate drivers 610 and 620. The data terminals DTD may be electrically connected to the data lines DL and the first routing lines RM1, and the gate terminals GTD may be electrically connected to the gate drivers 610 and 620 and the second routing lines RM2.

The connection line layer 500 may be disposed on a lower surface of the second single crystal semiconductor substrate 210. The connection line layer 500 may include an interlayer insulating film RINS and a plurality of connection lines RML1, RML2, and RML3.

The interlayer insulating film RINS may be disposed on the lower surface of the second single crystal semiconductor substrate 210. The interlayer insulating film RINS may be formed as a silicon carbonitride (SiCN) and/or silicon oxide (SiOₓ)-based inorganic film, but is not limited thereto. It has been illustrated in FIGS. 12 and 13 that the interlayer insulating film RINS is formed as a single layer, but the present disclosure is not limited thereto, and the interlayer insulating film RINS may also have a structure in which one or more layers are stacked, and the one or more layers may be disposed between the connection lines RML1, RML2, and RML3.

The connection lines RML1, RML2, and RML3 may form the routing lines RM1, RM2, and RM3 together with a plurality of conductive vias RVA1, RVA2, and RVA3. The connection lines RML1, RML2, and RML3 may include one or more conductive layers and one or more vias connecting the one or more conductive layers to each other. A description of connection and a structure of the connection lines RML1, RML2, and RML3 may be the same as the description of the plurality of conductive layers ML1 to ML8 and vias VA1 to VA8 described above. The connection lines RML1, RML2, and RML3 may be electrically connected to the pixel circuit unit 220 and/or the second pads PD2 through the conductive vias RVA1, RVA2, and RVA3 disposed in the through holes TSV1, TSV2, and TSV3 of the second single crystal semiconductor substrate 210, and may be electrically connected to the driving circuit layer 120 of the driving unit 100.

According to one or more embodiments, the display unit 200 of the display device 10 may include first through holes TSV1, second through holes TSV2, and third through holes TSV3 penetrating through the second single crystal semiconductor substrate 210. The first to third through holes TSV1, TSV2, and TSV3 may each be disposed in the non-display area NA. As described above, the first through holes TSV1 and the third through holes TSV3 may be disposed in the pad area PDA of the display unit 200 (e.g., see FIG. 4), and the second through holes TSV2 may be disposed to overlap the gate drivers 610 and 620 in the non-display area NA (e.g., see FIG. 4).

The first routing lines RM1 connecting the data terminals DTD connected to the data lines DL and the driving circuit layer 120 of the driving unit 100 to each other may be disposed in the first through holes TSV1. The first through hole TSV1 may penetrate through the second single crystal semiconductor substrate 210, the semiconductor insulating films SINS3 and SINS4, and the interlayer insulating films INS3, INS4, and INS5, and may penetrate from a lower surface of the data terminal DTD to the lower surface of the second single crystal semiconductor substrate 210. A first conductive via RVA1 may be disposed from the lower surface of the data terminal DTD to the lower surface of the second single crystal semiconductor substrate 210 and connected to each of the data terminal DTD and a first connection line RML1. The first connection line RML1 may be the data routing line GDL described above with reference to FIG. 7.

The second routing lines RM2 connecting the gate terminals GTD connected to the gate drivers 610 and 620 and the driving circuit layer 120 of the driving unit 100 to each other may be disposed in the second through holes TSV2. The second through hole TSV2 may penetrate through the second single crystal semiconductor substrate 210, the semiconductor insulating films SINS3 and SINS4, and the interlayer insulating films INS3, INS4, and INS5, and may penetrate from a lower surface of the gate terminal GTD to the lower surface of the second single crystal semiconductor substrate 210. A second conductive via RVA2 may be disposed from the lower surface of the gate terminal GTD to the lower surface of the second single crystal semiconductor substrate 210 and connected to each of the gate terminal GTD and a second connection line RML2. The second connection line RML2 may be the control routing line TCL described above with reference to FIG. 7.

A through hole and a conductive via disposed in the non-display area NA illustrated in FIG. 12 may be the first through hole TSV1 or the second through hole TSV2 and the first conductive via RVA1 or the second conductive via RVA2, respectively. A terminal illustrated in FIG. 12 may be the data terminal DTD or the gate terminal GTD. The first routing lines RM1 and the second routing lines RM2, and the first through holes TSV1 and the second through holes TSV2 are different from each other only in positions where they are disposed, the number, a connection relationship, and/or the like, and may be substantially the same as each other in a cross-sectional structure.

The third routing lines RM3 connecting the second pads PD2 disposed in the pad area PDA of the display unit 200 and the first pads PD1 of the driving unit 100 to each other may be disposed in the third through holes TSV3. The third through hole TSV3 may penetrate through the second single crystal semiconductor substrate 210, the semiconductor insulating films SINS3 and SINS4, and the interlayer insulating films INS3, INS4, and INS5, and may penetrate from a lower surface of the second pad PD2 to the lower surface of the second single crystal semiconductor substrate 210. A third conductive via RVA3 may be disposed from the lower surface of the second pad PD2 to the lower surface of the second single crystal semiconductor substrate 210 and connected to each of the second pad PD2 and a third connection line RML3.

In the display device 10, the circuit units formed in the driving unit 100 may be formed by a high-cost fine semiconductor process and thus formed with a high degree of integration on the first single crystal semiconductor substrate 110 having the small area. A manufacturing process of the driving unit 100 may have a high yield per unit wafer substrate, and the circuit elements (e.g., the first transistors) may have a small size, such that power consumption may also be reduced. In addition, by disposing a pixel circuit, some circuit elements, and lines for light emission of light emitting elements are disposed in the display unit 200, it is possible to prevent a degree of integration of the first single crystal semiconductor substrate 110 from becoming excessively high. In addition, by optimizing the number of through holes TSV1, TSV2, and TSV3 in which the routing lines RM1, RM2, and RM3 connecting the display unit 200 and the driving unit 100 to each other are disposed, a space where the through holes TSV1, TSV2, and TSV3 having suitable diameters (e.g., predetermined diameters) and intervals by which they are spaced (e.g., spaced apart) from each other are disposed may also be reduced or minimized.

The reflective electrode layer RL may be disposed on the seventh interlayer insulating film INS7. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 12.

Each of the first reflective electrodes RL1 may be disposed on the seventh interlayer insulating film INS7 and may be connected to a via penetrating through the seventh interlayer insulating film INS7. Each of the first reflective electrodes RL1 may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, each of the first reflective electrodes RL1 may include titanium nitride (TiN).

Each of the second reflective electrodes RL2 may be disposed on the first reflective electrode RL1. Each of the second reflective electrodes RL2 may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, each of the second reflective electrodes RL2 may include aluminum (Al).

Each of the third reflective electrodes RL3 may be disposed on the second reflective electrode RL2. Each of the third reflective electrodes RL3 may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, each of the third reflective electrodes RL3 may include titanium nitride (TIN).

Each of the fourth reflective electrodes RL4 may be disposed on the third reflective electrode RL3. Each of the fourth reflective electrodes RL4 may be made of copper (Cu), aluminum (Al), tungsten (W), molybdenum (Mo), chromium (Cr), gold (Au), titanium (Ti), nickel (Ni), and/or neodymium (Nd), and/or alloys thereof. For example, each of the fourth reflective electrodes RL4 may include titanium (Ti).

The second reflective electrodes RL2 are electrodes substantially reflecting light from the light emitting elements, and in one or more embodiments, a thickness of the second reflective electrode RL2 may be greater than a thickness of the first reflective electrode RL1, a thickness of the third reflective electrode RL3, and a thickness of the fourth reflective electrode RL4. For example, in one or more embodiments, the thickness of the first reflective electrode RL1, the third reflective electrode RL3, and the fourth reflective electrode RL4 may be approximately 100 Å, and the thickness of the second reflective electrode RL2 may be approximately 850 Å.

An eighth interlayer insulating film INS8 may be disposed on the seventh interlayer insulating film INS7. The eighth interlayer insulating film INS8 may be disposed between the reflective electrode layers RL adjacent to each other. The eighth interlayer insulating film INS8 may be disposed on the reflective electrode layer RL in the first sub-pixel SP1. The eighth interlayer insulating film INS8 may be formed as a silicon oxide (SiOₓ)-based inorganic film, but is not limited thereto.

A ninth interlayer insulating film INS9 may be disposed on the eighth interlayer insulating film INS8 and the reflective electrode layer RL. The ninth interlayer insulating film INS9 may be formed as a silicon oxide (SiOₓ)-based inorganic film, but is not limited thereto.

In at least one of the first sub-pixel SP1, the second sub-pixel SP2, and the third sub-pixel SP3, the eighth interlayer insulating film INS8 and/or the ninth interlayer insulating film INS9 may not be disposed below the first electrode AND, in consideration of a resonance distance of the light emitted from the light emitting elements LE.

For example, the first electrode AND of the third sub-pixel SP3 may be directly disposed on the fourth reflective electrode RL4, and may not overlap the eighth interlayer insulating film INS8 and the ninth interlayer insulating film INS9. The first electrode AND of the second sub-pixel SP2 may be disposed on the ninth interlayer insulating film INS9, and the ninth interlayer insulating film INS9 may be directly disposed on the fourth reflective electrode RL4. That is, the first electrode AND of the second sub-pixel SP2 may not overlap the eighth interlayer insulating film INS8. The first electrode AND of the first sub-pixel SP1 may be disposed on the ninth interlayer insulating film INS9, and may overlap the eighth interlayer insulating film INS8.

In one or more embodiments, a distance between the first electrode AND and the reflective electrode layer RL may be different in each of the first sub-pixel SP1, the second sub-pixel SP2, and the third sub-pixel SP3. In order to adjust a distance from the reflective electrode layer RL to a second electrode CAT according to a main wavelength of light emitted from each of the first sub-pixel SP1, the second sub-pixel SP2, and third the sub-pixel SP3, the presence or absence of the eighth interlayer insulating film INS8 and the ninth interlayer insulating film INS9 may be set in each of the first sub-pixel SP1, the second sub-pixel SP2, and the third sub-pixel SP3. For example, in FIG. 12, a distance between the first electrode AND and the reflective electrode layer RL in the first sub-pixel SP1 may be greater than a distance between the first electrode AND and the reflective electrode layer RL in the second sub-pixel SP2 and a distance between the first electrode AND and the reflective electrode layer RL in the third sub-pixel SP3, and the distance between the first electrode AND and the reflective electrode layer RL in the second sub-pixel SP2 may be greater than the distance between the first electrode AND and the reflective electrode layer RL in the third sub-pixel SP3. However, the present disclosure is not limited thereto. The distance between the first electrode AND and the reflective electrode layer RL in each of the sub-pixels SP1, SP2, and SP3 may be variously modified and designed.

In addition, it has been illustrated in FIGS. 12 and 13 that the eighth interlayer insulating film INS8 and the ninth interlayer insulating film INS9 are disposed, but a tenth interlayer insulating film may be further disposed below the first electrode AND of the sub-pixel SP. In this case, the ninth interlayer insulating film INS9 and the tenth interlayer insulating film may be disposed below the first electrode AND of the second sub-pixel SP2, and the eighth interlayer insulating film INS8, the ninth interlayer insulating film INS9, and the tenth interlayer insulating film may be disposed below the first electrode AND of the first sub-pixel SP1.

Each of electrode vias VAP may penetrate through the eighth interlayer insulating film INS8 and/or the ninth interlayer insulating film INS9 in the first sub-pixel SP1 and the second sub-pixel SP2 to be connected to the exposed fourth reflective electrode RL4. Each of the electrode vias VAP may be made of copper (Cu), aluminum (AI), tungsten (W), molybdenum (Mo), chromium (Cr), gold (Au), titanium (Ti), nickel (Ni), and/or neodymium (Nd), and/or alloys thereof. A thickness of the electrode via VAP in the second sub-pixel SP2 may be smaller than a thickness of the electrode via VAP in the first sub-pixel SP1.

The display element layer 230 may be disposed on the light emitting element backplane EBP. The display device layer 230 may include the light emitting element layer EML, the encapsulation layer TFE, an optical layer OPL, and the cover layer DCL. The display element layer 230 may include the light emitting elements electrically connected to the pixel circuit unit 220 and the driving unit 100 to emit light.

The light emitting element layer EML may be disposed on the reflective electrode layer RL and the ninth interlayer insulating film INS9. The light emitting element layer EML may include light emitting elements each including a first electrode AND, a light emitting stack IL, and a second electrode CAT, a pixel defining film PDL, and a plurality of trenches TRC.

The first electrode AND of each of the light emitting elements may be disposed on the ninth interlayer insulating film INS9 or the reflective electrode layer RL and may be connected to the electrode via VAP. The first electrode AND of each of the light emitting elements LE may be connected to the second transistor PTR2 through the electrode via VAP, the first to fourth reflective electrodes RL1 to RL4, the routing conductive layer RMT, and the contact electrode CTE. The first electrode AND of each of the light emitting elements may be made of copper (Cu), aluminum (AI), tungsten (W), molybdenum (Mo), chromium (Cr), gold (Au), titanium (Ti), nickel (Ni), and/or neodymium (Nd), and/or alloys thereof. For example, the first electrode AND of each of the light emitting elements may be made of titanium nitride (TiN).

The pixel defining film PDL may be disposed on a partial area of the first electrode AND of each of the light emitting elements. The pixel defining film PDL may cover an edge of the first electrode AND of each of the light emitting elements. The pixel defining film PDL serves to partition the first emission areas EA1, the second emission areas EA2, and the third emission areas EA3.

The first emission area EA1 may be defined as an area where the first electrode AND, the light emitting stack IL, and the second electrode CAT are sequentially stacked in the first sub-pixel SP1 to emit light. The second emission area EA2 may be defined as an area where the first electrode AND, the light emitting stack IL, and the second electrode CAT are sequentially stacked in the second sub-pixel SP2 to emit light. The third emission area EA3 may be defined as an area where the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but are not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first inorganic encapsulation layer TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

In order to prevent the first inorganic encapsulation layer TFE1 from being disconnected due to the step coverage, the first pixel defining film PDL1, the second pixel defining film PDL2, and the third pixel defining film PDL3 may have a cross-sectional structure with a step having a staircase shape. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length of the first pixel defining film PDL1 in a horizontal direction defined by the first direction DR1 and the second direction DR2.

Each of the plurality of trenches TRC may penetrate through the first pixel defining film PDL1, the second pixel defining film PDL2, and the third pixel defining film PDL3. In each of the plurality of trenches TRC, a portion of the eighth interlayer insulating film INS8 may be trenched and the ninth interlayer insulating film INS9 may be penetrated.

At least one trench TRC may be disposed between the sub-pixels SP1, SP2, and SP3 neighboring each other. It has been illustrated in FIGS. 12 and 13 that two trenches TRC are disposed between the sub-pixels SP1, SP2, and SP3 neighboring each other, but the present disclosure is not limited thereto.

The light emitting stack IL may include a plurality of intermediate layers. It has been illustrated in FIGS. 12 and 13 that the light emitting stack IL has a three-tandem structure including a first intermediate layer IL1, a second intermediate layer IL2, and a third intermediate layer IL3, but the present disclosure is not limited thereto. For example, the light emitting stack IL may have a two-tandem structure including two intermediate layers.

In the three-tandem structure, the light emitting stack IL may have a tandem structure including a plurality of intermediate layers IL1, IL2, and IL3 emitting different light. For example, the light emitting stack IL may include a first intermediate layer IL1 emitting a first light, a second intermediate layer IL2 emitting a third light, and a third intermediate layer IL3 emitting a second light. The first intermediate layer IL1, the second intermediate layer IL2, and the third intermediate layer IL3 may be sequentially stacked.

The first intermediate layer IL1 may have a structure in which a first hole transporting layer, a first organic light emitting layer emitting the first light, and a first electron transporting layer are sequentially stacked. The second intermediate layer IL2 may have a structure in which a second hole transporting layer, a second organic light emitting layer emitting the third light, and a second electron transporting layer are sequentially stacked. The third intermediate layer IL3 may have a structure in which a third hole transporting layer, a third organic light emitting layer emitting the second light, and a third electron transporting layer are sequentially stacked.

A first charge generation layer for supplying charges to the second intermediate layer IL2 and supplying electrons to the first intermediate layer IL1 may be disposed between the first intermediate layer IL1 and the second intermediate layer IL2. The first charge generation layer may include an N-type charge generation layer supplying electrons to the first intermediate layer IL1 and a P-type charge generation layer supplying holes to the second intermediate layer IL2. The N-type charge generation layer may include a dopant of a metal material.

A second charge generation layer for supplying charges to the third intermediate layer IL3 and supplying electrons to the second intermediate layer IL2 may be disposed between the second intermediate layer IL2 and the third intermediate layer IL3. The second charge generation layer may include an N-type charge generation layer supplying electrons to the second intermediate layer IL2 and a P-type charge generation layer supplying holes to the third intermediate layer IL3.

The first intermediate layer IL1 may be disposed on the first electrodes AND and the pixel defining film PDL, and may be disposed on a bottom surface of each of the trenches TRC. Due to the trenches TRC, the first intermediate layer IL1 may be disconnected between the sub-pixels SP1, SP2, and SP3 neighboring each other. The second intermediate layer IL2 may be disposed on the first intermediate layer IL1. Due to the trenches TRC, the second intermediate layer IL2 may be disconnected between the sub-pixels SP1, SP2, and SP3 neighboring each other. A cavity or an empty space may be disposed between the first intermediate layer IL1 and the second intermediate layer IL2. The third intermediate layer IL3 may be disposed on the second intermediate layer IL2. The third intermediate layer IL3 may not be disconnected by the trenches TRC, and may be disposed to cover the second intermediate layer IL2 in each of the trenches TRC. That is, in the three-tandem structure, each of the plurality of trenches TRC may be a structure for disconnecting the first and second intermediate layers IL1 and IL2, the first charge generation layer, and the second charge generation layer of the light emitting element layer EML between the sub-pixels SP1, SP2, and SP3 neighboring each other. In addition, in the two-tandem structure, each of the plurality of trenches TRC may be a structure for disconnecting a charge generation layer disposed between a lower intermediate layer and an upper intermediate layer and the lower intermediate layer.

In order to stably disconnect the first and second intermediate layers IL1 and IL2 of the light emitting element layer EML between the sub-pixels SP1, SP2, and SP3 neighboring each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second intermediate layers IL1 and IL2 of the light emitting element layer EML between the sub-pixels SP1, SP2, and SP3 neighboring each other, other structures may exist instead of the trenches TRC. For example, instead of the trenches TRC, partition walls having a reverse tapered shape may be disposed on the pixel defining film PDL.

The number of intermediate layers IL1, IL2, and IL3 emitting the different light is not limited to that illustrated in FIGS. 12 and 13. For example, the light emitting stack IL may include two intermediate layers. In this case, one of the two intermediate layers may be substantially the same as the first intermediate layer IL1, and the other of the two intermediate layers may include a second hole transporting layer, a second organic light emitting layer, a third organic light emitting layer, and a second electron transporting layer. In this case, a charge generation layer for supplying electrons to one intermediate layer and supplying charges to the other intermediate layer may be disposed between the two intermediate layers.

In addition, it has been illustrated in FIGS. 12 and 13 that the first to third intermediate layers IL1, IL2, and IL3 are all disposed in the first emission area EA1, the second emission area EA2, and the third emission area EA3, but the present disclosure is not limited thereto. For example, the first intermediate layer IL1 may be disposed in the first emission area EA1, and may not be disposed in the second emission area EA2 and the third emission area EA3. In addition, the second intermediate layer IL2 may be disposed in the second emission area EA2, and may not be disposed in the first emission area EA1 and the third emission area EA3. In addition, the third intermediate layer IL3 may be disposed in the third emission area EA3, and may not be disposed on the first emission area EA1 and the second emission area EA2. In this case, first to third color filters CF1, CF2, and CF3 of the color filter layer CFL may be omitted.

The second electrode CAT may be disposed on the third intermediate layer IL3. The second electrode CAT may be disposed on the third intermediate layer IL3 in each of the plurality of trenches TRC. The second electrode CAT may be made of a transparent conductive material (TCO) such as indium tin oxide (ITO) or indium zinc oxide (IZO) capable of transmitting light therethrough and/or a semi-transmissive conductive material such as magnesium (Mg), silver (Ag), and/or an alloy of magnesium (Mg) and/or silver (Ag). When the second electrode CAT is made of the semi-transmissive conductive material, light emission efficiency of each of the first to third sub-pixels SP1, SP2, and SP3 may be increased by a micro cavity.

The encapsulation layer TFE may be disposed on the light emitting element layer EML. The encapsulation layer TFE may include at least one inorganic encapsulation layer TFE1 and TFE3 in order to prevent oxygen or moisture from permeating into the light emitting element layer EML. In addition, the encapsulation layer TFE may include at least one organic film in order to protect the light emitting element layer EML from foreign substances such as dust. For example, the encapsulation layer TFE may include a first inorganic encapsulation layer TFE1, an organic encapsulation layer TFE2, and a second inorganic encapsulation layer TFE3.

The first inorganic encapsulation layer TFE1 may be disposed on the second electrode CAT, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed as multiple films in which one or more inorganic films of a silicon nitride (SiNx) layer, a silicon oxynitride (SiOₓN_{y}) layer, a silicon oxide (SiOₓ) layer, a titanium oxide (TiOx) layer, and/or an aluminum oxide (AlOₓ) layer are alternately stacked. The organic encapsulation layer TFE2 may be made of a monomer. Alternatively, the organic encapsulation layer TFE2 may be an organic film made of an acrylic resin, an epoxy resin, a phenolic resin, a polyamide resin, a polyimide resin, and/or the like.

The adhesive layer ADL may be disposed on the encapsulation layer TFE. The adhesive layer ADL may be a layer for adhering the encapsulation layer TFE and a layer disposed thereon to each other. The adhesive layer ADL may be a double-sided adhesive member. In addition, the adhesive layer ADL may be a transparent adhesive member such as a transparent adhesive or a transparent adhesive resin.

The optical layer OPL may include a color filter layer CFL, a plurality of lenses LNS, and a filling layer FIL. The color filter layer CFL may include first to third color filters CF1, CF2, and CF3. The first to third color filters CF1, CF2, and CF3 may be disposed on the adhesive layer ADL.

The first color filter CF1 may overlap the first emission area EA1. The first color filter CF1 may transmit the first light, that is, the light of the red wavelength band, therethrough. The red wavelength band may be approximately 600 nm to 750 nm. The first color filter CF1 may transmit the first light from among light emitted from the first emission area EA1 therethrough.

The second color filter CF2 may overlap the second emission area EA2. The second color filter CF2 may transmit the second light, that is, the light of the green wavelength band, therethrough. The green wavelength band may be approximately 480 nm to 560 nm. The second color filter CF2 may transmit the second light from among light emitted from the second emission area EA2 therethrough.

The third color filter CF3 may overlap the third emission area EA3. The third color filter CF3 may transmit the third light, that is, the light of the blue wavelength band, therethrough. The blue wavelength band may be approximately 370 nm to 460 nm. The third color filter CF3 may transmit the third light from among light emitted from the third emission area EA3 therethrough.

Each of the plurality of lenses LNS may be disposed on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction.

The filling layer FIL may be disposed on the plurality of lenses LNS. The filling layer FIL may have a suitable refractive index (e.g., a predetermined refractive index) so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, and/or the like.

The cover layer DCL may be disposed on the filling layer FIL. The cover layer DCL may be a glass substrate and/or a polymer resin such as a resin. When the cover layer DCL is the glass substrate, the cover layer DCL may be attached onto the filling layer FIL. In this case, the filling layer FIL may serve to adhere the cover layer DCL. When the cover layer DCL is the glass substrate, the cover layer DCL may serve as an encapsulation substrate. When the cover layer DCL is the polymer resin such as the resin, the cover layer DCL may be directly applied onto the filling layer FIL. In one or more embodiments, the display unit 200 may further include a polarizing plate disposed on the cover layer DCL. The polarizing plate may be disposed on one surface of the cover layer DCL. The polarizing plate may be a structure for preventing or reducing deterioration in visibility due to external light reflection. The polarizing plate may include a linear polarizing plate and a phase retardation film. For example, the phase retardation film may be a λ/4 plate (e.g., a quarter-wave plate), but is not limited thereto. However, when visibility due to external light reflection is sufficiently improved by the first to third color filters CF1, CF2, and CF3, the polarizing plate may be omitted.

Hereinafter, various embodiments of the display device 10 will be described with reference to other drawings.

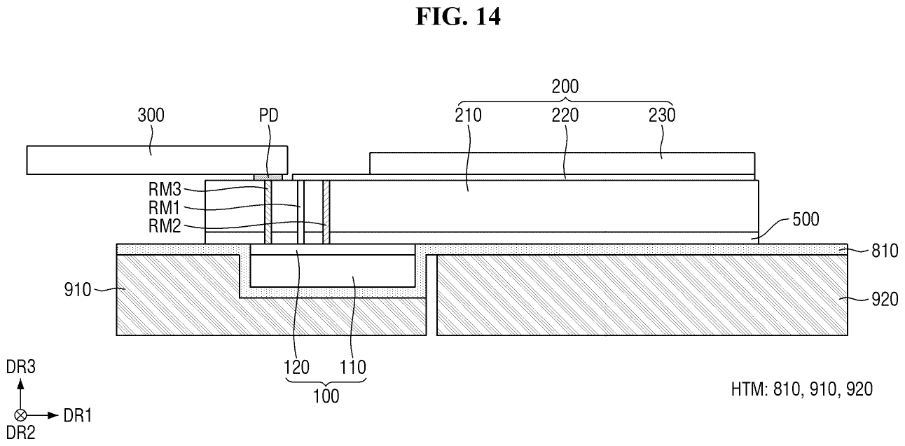

FIG. 14 is a schematic cross-sectional view of a display device according to one or more embodiments.

Referring to FIG. 14, in a display device 10 according to one or more embodiments, the heat dissipation member HTM may protrude more than outer side surfaces of the display unit 200. In the display device 10, side surfaces of the heat dissipation layer 810 and the heat dissipation substrates 910 and 920 of the heat dissipation member HTM may not be parallel to side surfaces of the display unit 200. In the display device 10, an area of an area surrounded by the side surfaces of the heat dissipation member HTM may be greater than an area of the display unit 200 in a plan view.

For example, an area of the heat dissipation layer 810 in a plan view may be greater than the area of the display unit 200 in a plan view, and portions disposed on the lower surface of the display unit 200 may protrude more than the side surfaces of the display unit 200. The heat dissipation layer 810 may protrude in parallel from each side surface of the display unit 200 in the first direction DR1 and/or the second direction DR2. The first heat dissipation substrate 910 and the second heat dissipation substrate 920 may each be disposed on a lower surface of the heat dissipation layer 810, and side surfaces of each of the first heat dissipation substrate 910 and the second heat dissipation substrate 920 may be parallel to side surfaces of the heat dissipation layer 810. The first heat dissipation substrate 910 and the second heat dissipation substrate 920 may also each protrude more than the side surface of the display unit 200.

In the display device 10 according to one or more embodiments, the heat dissipation layer 810 of the heat dissipation member HTM may be disposed to have a greater area than the display unit 200 and the driving unit 100, and may dissipate heat generated by the driving unit 100 and the display unit 200 while spreading the heat over a wider area. The display device 10 may manage heat generation more effectively by forming the heat dissipation member HTM so as to have a great area.

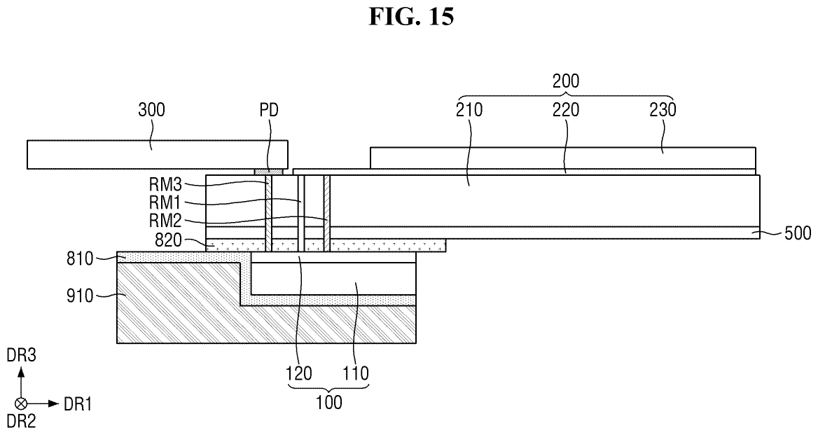

FIGS. 15-18 are schematic cross-sectional views of display devices according to one or more embodiments.

Referring to FIG. 15, in a display device 10 according to one or more embodiments, the heat dissipation member HTM may further include a heat blocking layer 820 disposed between the display unit 200 and the driving unit 100. The heat blocking layer 820 may be disposed to overlap the driving unit 100, and may overlap the plurality of through holes TSV1, TSV2, and TSV3 in which the routing lines RM1, RM2, and RM3 are disposed. In the display device 10, a large amount of heat may be generated in a portion of the driving unit 100 connected to the display unit 200, and the heat blocking layer 820 may prevent or reduce heat generated from the driving unit 100 from being transferred to the display unit 200. In one or more embodiments, the heat blocking layer 820 may include a material having lower thermal conductivity than the single crystal semiconductor substrates 110 and 210, and may prevent the heat generated from the driving unit 100 from spreading to the display unit 200.

In one or more embodiments, the heat blocking layer 820 may be disposed between the driving unit 100 and the display unit 200, may overlap the routing lines RM1, RM2, and RM3, and may include a plurality of through holes in which connection lines electrically connected to the routing lines RM1, RM2, and RM3 are disposed. The heat blocking layer 820 may include the through holes in which the connection lines may be disposed, similar to the through holes formed in the second single crystal semiconductor substrate 210, and the connection lines connected to the routing lines RM1, RM2, and RM3 may pass through the heat blocking layer 820 and may be connected to the driving unit 100. In one or more embodiments, at least a portion of the second single crystal semiconductor substrate 210 does not overlap the heat dissipation layer 810.

As the heat dissipation member HTM includes the heat blocking layer 820, the heat dissipation layer 810 and the heat dissipation substrate 910 may be disposed to overlap the driving unit 100. The heat dissipation layer 810 and the heat dissipation substrate 910 may be disposed to be biased to the other side in the first direction DR1 with respect to the center of the display device 10, and may be disposed to cover the driving unit 100. Unlike an embodiment of FIG. 8, the heat dissipation layer 810 may be disposed to overlap the heat blocking layer 820 around the driving unit 100, and may not be disposed in a portion of the display unit 200 that does not overlap the heat blocking layer 820. The heat dissipation substrate 910 may also be disposed on the heat dissipation layer 810, and may not be disposed in the portion of the display unit 200 that does not overlap the heat blocking layer 820. The heat dissipation layer 810 and the heat dissipation substrate 910 are disposed smaller than those of an embodiment of FIG. 7, and may accordingly protrude more than a lower side surface of the display unit 200, which is the other side surface of the display unit 200 in the first direction DR1. Portions of the heat dissipation layer 810 and the heat dissipation substrate 910 that protrude more than the display unit 200 may overlap the circuit board 300 in the third direction DR3.

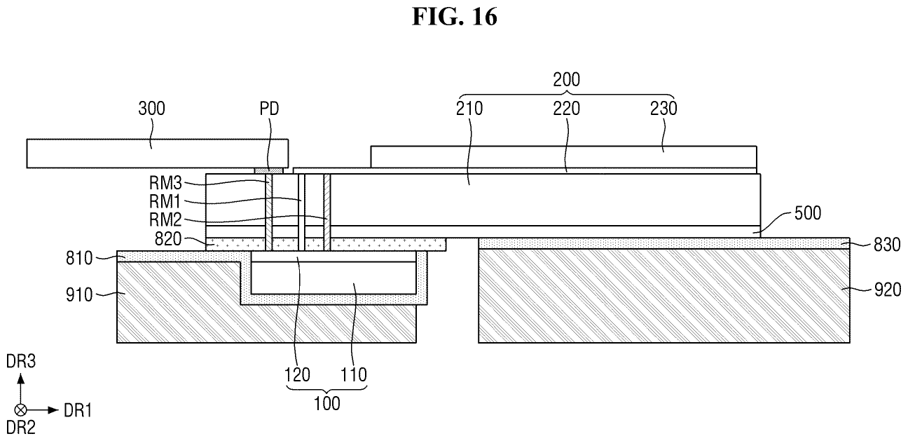

Referring to FIG. 16, in a display device 10 according to one or more embodiments, the heat dissipation member HTM may include heat dissipation layers 810 and 830 and heat dissipation substrates 910 and 920 entirely disposed on the display unit 200 in addition to the heat blocking layer 820. The display device 10 according to the present embodiment is different from the display device according to still another embodiment of FIG. 15 in that it further includes a second heat dissipation layer 830 and a second heat dissipation substrate 920 disposed below a portion of the display unit 200 that does not overlap the heat blocking layer 820.

The second heat dissipation layer 830 may include substantially the same material as the first heat dissipation layer 810, and may be disposed on the lower surface of the display unit 200. The second heat dissipation layer 830 may be entirely disposed below the portion of the display unit 200 that does not overlap the heat blocking layer 820, and may be formed to protrude more than a side surface of the display unit 200. The second heat dissipation layer 830 may be disposed to be spaced (e.g., spaced apart) from the heat blocking layer 820, and may not overlap the driving unit 100. The second heat dissipation substrate 920 may be disposed on a lower surface of the second heat dissipation layer 830, similar to the first heat dissipation substrate 910. The display device 10 may dissipate heat more effectively by including more heat dissipation layers 810 and 830 and heat dissipation substrates 910 and 920.

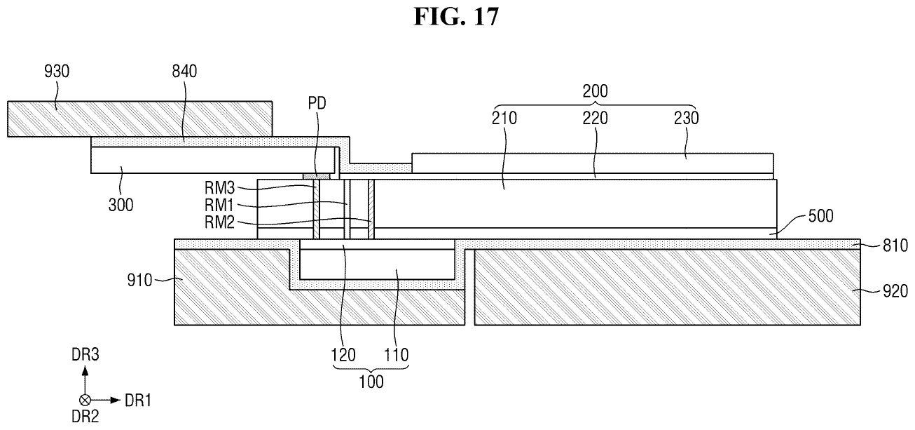

Referring to FIG. 17, in a display device 10 according to one or more embodiments, the heat dissipation member HTM may further include a heat dissipation layer 840 and a heat dissipation substrate 930 disposed on the circuit board 300. The present embodiment is different from another embodiment of FIG. 14 in that the heat dissipation member HTM of the display device 10 further includes a third heat dissipation layer 840 and a third heat dissipation substrate 930.

The display device 10 may further include the third heat dissipation layer 840 disposed on the circuit board 300 and the non-display area NA of the display unit 200. The third heat dissipation layer 840 may overlap the circuit board 300 and the through holes TSV1, TSV2, and TSV3 formed in the display unit 200. The third heat dissipation layer 840 may spread heat generated from the circuit board 300 and the routing lines RM1, RM2, and RM3 disposed in the display unit 200.

The third heat dissipation substrate 930 may be disposed on the third heat dissipation layer 840 on the circuit board 300. In one or more embodiments, the third heat dissipation board 930 may not overlap the display unit 200 and the driving unit 100, and may overlap only the circuit board 300. However, in one or more other embodiments, the third heat dissipation board 930 may at least partially overlap the display unit 200. The third heat dissipation substrate 930 may protrude more than a surface side of the circuit board 300, and may effectively dissipate the heat transferred through the third heat dissipation layer 840.

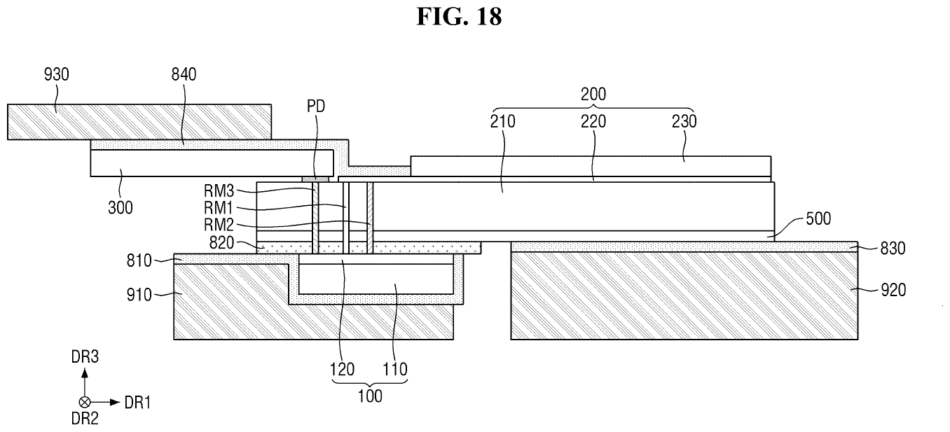

Referring to FIG. 18, a display device 10 according to one or more embodiments may be different from the display device 10 of FIG. 17 in that it further includes a heat blocking layer 820 disposed between the display unit 200 and the driving unit 100. The present embodiment may be considered as an embodiment in which configurations of the display device 10 of FIG. 16 and the display device 10 of FIG. 17 are combined with each other. The display device 10 according to the present embodiment has substantially the same structure as the above-described embodiments, and a detailed description thereof is thus omitted.

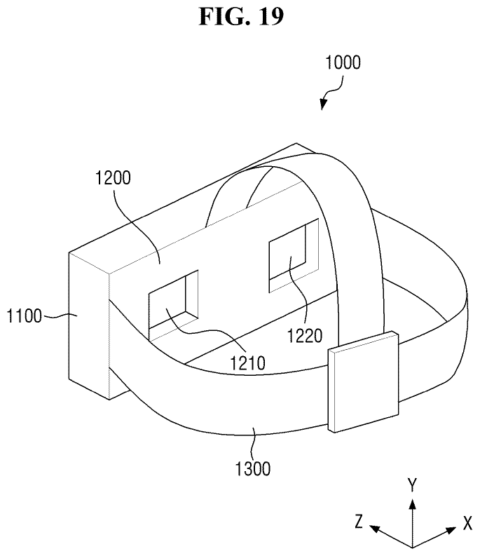

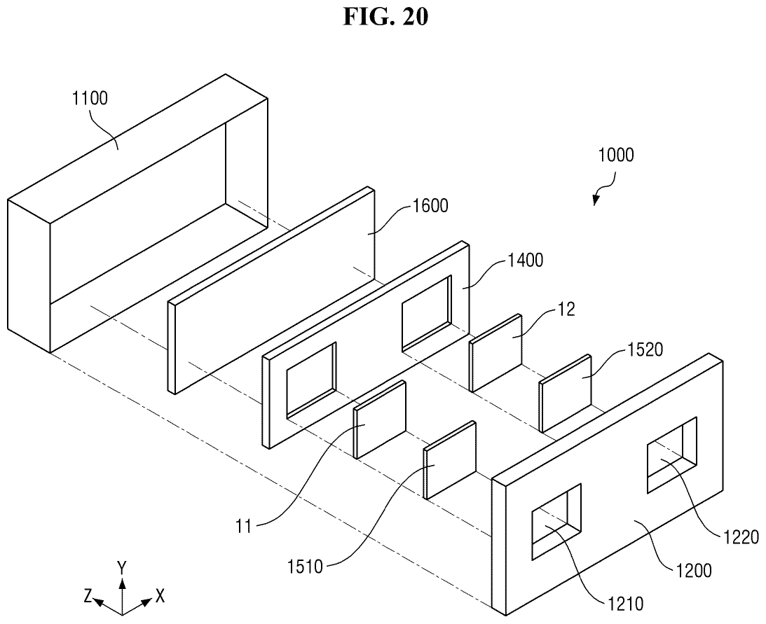

FIG. 19 is a perspective view illustrating a head mounted display device according to one or more embodiments. FIG. 20 is an exploded perspective view illustrating an example of the head mounted display device of FIG. 19.

Referring to FIGS. 19 and 20, a head mounted display device 1000 according to one or more embodiments includes a first display device 11, a second display device 12, a display device housing portion 1100, a housing portion cover 1200, a first eyepiece 1210, a second eyepiece 1220, a head mounted band 1300, a middle frame 1400, a first optical member 1510, a second optical member 1520, a control circuit board 1600, and a connector.

The first display device 11 provides an image to a user's left eye, and the second display device 12 provides an image to a user's right eye. Each of the first display device 11 and the second display device 12 is substantially the same as the display device 10 described with reference to FIG. 1, and a description of the first display device 11 and the second display device 12 is thus omitted.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1400 may be disposed between the first display device 11 and the control circuit board 1600 and disposed between the second display device 12 and the control circuit board 1600. The middle frame 1400 serves to support and fix the first display device 11, the second display device 12, and the control circuit board 1600.

The control circuit board 1600 may be disposed between the middle frame 1400 and the display device housing portion 1100. The control circuit board 1600 may be connected to the first display device 11 and the second display device 12 through the connector. The control circuit board 1600 may convert an image source input from the outside into digital video data DATA, and transmit the digital video data DATA to the first display device 11 and the second display device 12 through the connector.

The control circuit board 1600 may transmit digital video data DATA corresponding to a left eye image optimized for the user's left eye to the first display device 11 and transmit digital video data DATA corresponding to a right eye image optimized for the user's right eye to the second display device 12. Alternatively, the control circuit board 1600 may transmit the same digital video data DATA to the first display device 11 and the second display device 12.

The display device housing portion 1100 serves to house the first display device 11, the second display device 12, the middle frame 1400, the first optical member 1510, the second optical member 1520, the control circuit board 1600, and the connector. The housing portion cover 1200 is disposed to cover opened one surface of the display device housing portion 1100. The housing portion cover 1200 may include the first eyepiece 1210 on which the user's left eye is disposed and the second eyepiece 1220 on which the user's right eye is disposed. It has been illustrated in FIGS. 19 and 20 that the first eyepiece 1210 and the second eyepiece 1220 are separately disposed, but the present disclosure is not limited thereto. The first eyepiece 1210 and the second eyepiece 1220 may be merged as one eyepiece.

The first eyepiece 1210 may be aligned with the first display device 11 and the first optical member 1510, and the second eyepiece 1220 may be aligned with the second display device 12 and the second optical member 1520. Accordingly, a user may view an image of the first display device 11 magnified as a virtual image by the first optical member 1510 through the first eyepiece 1210, and may view an image of the second display device 12 magnified as a virtual image by the second optical member 1520 through the second eyepiece 1220.

The head mounted band 1300 serves to fix the display device housing portion 1100 to a user's head so that the first eyepiece 1210 and the second eyepiece 1220 of the housing portion cover 1200 may be maintained in a state in which they are disposed on the user's left eye and right eye, respectively. When the display device housing portion 1200 is implemented to have a light weight and a small size, the head mounted display device 1000 may include an eyeglass instead of the head mounted band 1300.

In addition, the head mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, and/or a Bluetooth module.

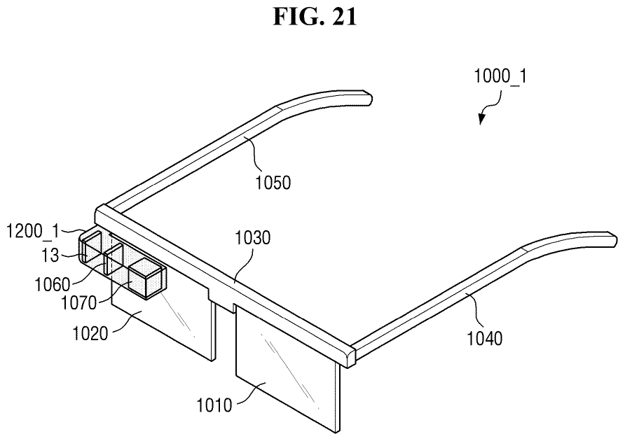

FIG. 21 is a perspective view illustrating a head mounted display device according to one or more embodiments.

Referring to FIG. 21, a head mounted display device 1000_1 according to one or more embodiments may be a glasses-type display device in which a display device housing portion 1200_1 is implemented to have a light weight and a small size. The head mounted display device 1000_1 according to one or more embodiments may include a display device 13, a left eye lens 1010, a right eye lens 1020, a support frame 1030, glasses frame legs 1040 and 1050, an optical member 1060, an optical path conversion member 1070, and a display device housing portion 1200_1.

The display device housing portion 1200_1 may include the display device 13, the optical member 1060, and the optical path conversion member 1070. An image displayed on the display device 13 may be magnified by the optical member 1060, converted in an optical path by the optical path conversion member 1070, and provided to a user's right eye through the right eye lens 1020. For this reason, a user may view an augmented reality image in which a virtual image displayed on the display device 13 through his/her right eye and a real image seen through the right eye lens 1020 are combined with each other.

It has been illustrated in FIG. 21 that the display device housing portion 1200_1 is disposed at a right end of the support frame 1030, but the present disclosure is not limited thereto. For example, the display device housing portion 1200_1 may be disposed at a left end of the support frame 1030, and in this case, an image of the display device 13 may be provided to a user's left eye. Alternatively, the display device housing portions 1200_1 may be disposed at both the left and right ends of the support frame 1030, and in this case, the user may view an image displayed on the display device 13 through both his/her left and right eyes.

In concluding the detailed description, those skilled in the art will appreciate that many variations and modifications can be made to the embodiments without substantially departing from the aspects of the present disclosure. Therefore, the embodiments of the present disclosure are used in a generic and descriptive sense only and not for purposes of limitation.

What is claimed is:

1. A display device comprising:
a first single crystal semiconductor substrate on which a plurality of first transistors are located;
a second single crystal semiconductor substrate on the first single crystal semiconductor substrate, the second single crystal semiconductor substrate having a display area;
a plurality of sub-pixels comprising light emitting elements at the display area of the second single crystal semiconductor substrate,
a plurality of first through holes having first conductive vias electrically connected to a plurality of data lines connected to the plurality of sub-pixels, and a plurality of second through holes having second conductive vias electrically connected to a gate driver electrically connected to the sub-pixels; and
a heat dissipating member around the first single crystal semiconductor substrate below the second single crystal semiconductor substrate and overlapping each of the plurality of first through holes and the second through holes,
wherein the heat dissipation member comprises a first heat dissipation layer in contact with each of a lower surface and side surfaces of the first single crystal semiconductor substrate and a first heat dissipation substrate on a lower surface of the first heat dissipation layer, and
wherein an area of the first single crystal semiconductor substrate in a plan view is smaller than an area of the second single crystal semiconductor substrate in a plan view.

2. The display device of claim 1, wherein the first heat dissipation layer covers the lower surface and the side surfaces of the first single crystal semiconductor substrate and overlaps a portion of a lower surface of the second single crystal semiconductor substrate that does not overlap the first single crystal semiconductor substrate, and
wherein the heat dissipation member further comprises a second heat dissipation substrate overlapping a portion of the second single crystal semiconductor substrate where the first single crystal semiconductor substrate is not located.

3. The display device of claim 2, wherein the first heat dissipation layer overlaps the display area in a thickness direction of the display device.

4. The display device of claim 2, further comprising a circuit board on the second single crystal semiconductor substrate and overlapping the plurality of first through holes,
wherein the heat dissipation member further comprises a third heat dissipation layer on the circuit board and a third heat dissipation substrate on the third heat dissipation layer.

5. The display device of claim 4, wherein the third heat dissipation layer is on a portion of the second single crystal semiconductor substrate where the first through holes are located, and
wherein the third heat dissipation substrate does not overlap the second single crystal semiconductor substrate.

6. The display device of claim 4, wherein the second single crystal semiconductor substrate further includes a plurality of third through holes overlapping pads, and
wherein the plurality of first through holes overlap the circuit board in a thickness direction of the display device.

7. The display device of claim 2, wherein outer side surfaces of each of the first heat dissipation layer, the first heat dissipation substrate, and the second heat dissipation substrate are parallel to side surfaces of the second single crystal semiconductor substrate.

8. The display device of claim 2, wherein outer side surfaces of each of the first heat dissipation layer, the first heat dissipation substrate, and the second heat dissipation substrate protrude outward more than side surfaces of the second single crystal semiconductor substrate.

9. The display device of claim 1, wherein the heat dissipation member further comprises a heat blocking layer between the first single crystal semiconductor substrate and the second single crystal semiconductor substrate,
wherein the heat blocking layer comprises a plurality of through holes in which connection lines penetrating through the heat blocking layer and electrically connected respectively to the first conductive vias and the second conductive vias are located.

10. The display device of claim 9, wherein the first heat dissipation layer overlaps the first single crystal semiconductor substrate, and
wherein at least a portion of the second single crystal semiconductor substrate does not overlap the first heat dissipation layer.

11. The display device of claim 9, wherein the first heat dissipation layer covers the lower surface and the side surfaces of the first single crystal semiconductor substrate, and
wherein the heat dissipation member further includes a second heat dissipation layer overlapping a portion of a lower surface of the second single crystal semiconductor substrate that does not overlap the first single crystal semiconductor substrate, and a second heat dissipation substrate on a lower surface of the second heat dissipation layer.

12. The display device of claim 11, further comprising a circuit board on the second single crystal semiconductor substrate and overlapping the plurality of first through holes,
wherein the heat dissipation member further comprises a third heat dissipation layer on the circuit board and a third heat dissipation substrate on the third heat dissipation layer.

13. The display device of claim 1, wherein a number of the first through holes is the same as a number of pixel columns of the sub-pixels arranged in the display area.

14. The display device of claim 13, wherein the data lines extend in a first direction on the second single crystal semiconductor substrate, and are electrically connected to at least some of the first transistors,
wherein the display device further comprises a plurality of scan lines extending in a second direction crossing the first direction on the second single crystal semiconductor substrate and electrically connected to the gate driver, and
wherein the number of the first through holes is the same as a number of data lines.

15. The display device of claim 1, wherein a width of the first single crystal semiconductor substrate measured in one direction is greater than a width of the display area measured in the one direction.

16. A head mounted display device comprising:
a frame;
a plurality of display devices in the frame; and
lenses on the plurality of display devices, respectively,
wherein the display device comprises:
a first single crystal semiconductor substrate on which a plurality of first transistors are located;
a second single crystal semiconductor substrate disposed on the first single crystal semiconductor substrate, the second single crystal semiconductor substrate having a display area;
a plurality of sub-pixels comprising light emitting elements at the display area of the second single crystal semiconductor substrate;
a plurality of first through holes having first conductive vias electrically connected to a plurality of data lines connected to the plurality of sub-pixels are disposed, and a plurality of second through holes having second conductive vias electrically connected to a gate driver electrically connected to the sub-pixels; and
a heat dissipating member around the first single crystal semiconductor substrate below the second single crystal semiconductor substrate and overlapping each of the plurality of first through holes and the second through holes,
the heat dissipation member comprising a first heat dissipation layer in contact with each of a lower surface and side surfaces of the first single crystal semiconductor substrate and a first heat dissipation substrate disposed on a lower surface of the first heat dissipation layer, and
an area of the first single crystal semiconductor substrate in a plan view is smaller than an area of the second single crystal semiconductor substrate in a plan view.

17. The head mounted display device of claim 16, wherein the first heat dissipation layer covers the lower surface and the side surfaces of the first single crystal semiconductor substrate and overlaps a portion of a lower surface of the second single crystal semiconductor substrate that does not overlap the first single crystal semiconductor substrate, and
wherein the heat dissipation member further comprises a second heat dissipation substrate overlapping a portion of the second single crystal semiconductor substrate where the first single crystal semiconductor substrate is not located.

18. The head mounted display device of claim 16, wherein the heat dissipation member further comprises a heat blocking layer between the first single crystal semiconductor substrate and the second single crystal semiconductor substrate,
wherein the heat blocking layer includes a plurality of through holes in which connection lines penetrating through the heat blocking layer and electrically connected respectively to the first conductive vias and the second conductive vias are located.

19. The head mounted display device of claim 18, wherein the first heat dissipation layer overlaps the first single crystal semiconductor substrate, and
wherein at least a portion of the second single crystal semiconductor substrate does not overlap the first heat dissipation layer.

20. The head mounted display device of claim 18, wherein the first heat dissipation layer covers the lower surface and the side surfaces of the first single crystal semiconductor substrate, and
wherein the heat dissipation member further comprises a second heat dissipation layer overlapping a portion of a lower surface of the second single crystal semiconductor substrate that does not overlap the first single crystal semiconductor substrate, and a second heat dissipation substrate disposed on a lower surface of the second heat dissipation layer.
